(19) United States
(12) Patent Application Publication
(10) Pub. No.: US 2007/0090493 A1
(43) Pub. Date: Apr. 26, 2007

(54) Fabrication of nitrogen containing regions on silicon containing regions in integrated circuits, and integrated circuits obtained thereby

(75) Inventors: Zhong Dong, San Jose, CA (US); Chiliang Chen, Sunnyvale, CA (US); Chung Wai Leung, Milpitas, CA (US)

Correspondence Address: MACPHERSON KWOK CHEN & HEID LLP, 2033 GATEWAY PLACE, SUITE 400, SAN JOSE, CA, 95110, US

(73) Assignee: ProMOS Technologies Inc.

(21) Appl. No.: 11/248,705

(22) Filed: Oct. 11, 2005

(51) Int. Cl. H01L 23/58; H01L 21/318

(52) U.S. Cl. 257/632; 438/770; 438/775; 257/649

(57) ABSTRACT

Silicon oxide (210) is grown on a silicon region (130). At least a portion (210N) of the silicon oxide (210) adjacent to the silicon region (130) is nitrided. Then some of the silicon oxide (210) is removed, leaving the nitrided portion (210N). Additional silicon oxide is thermally grown on the silicon region (130) under the nitrided silicon oxide portion (210N). This additional silicon oxide and the nitrided portion (210N) form a silicon oxide layer (140) having a high nitrogen concentration adjacent to a surface opposite from the silicon region (130) and a low nitrogen concentration elsewhere. Another nitridation step increases the nitrogen concentration in the silicon oxide layer (140) adjacent to the silicon region, providing a double peak nitrogen profile.

### BACKGROUND OF THE INVENTION

The present invention relates to integrated circuits, and more particularly to circuits using nitrided silicon oxide.

FIG. 1 shows a cross section of a MOS transistor. Source/drain regions 110 and a channel region 120 are formed in a monocrystalline silicon substrate 130. Silicon dioxide 140 separates the regions 110, 120, 130 from polysilicon gate 150. The regions 110, 120, 150 are doped to provide desired conductivity. Disadvantageously, the dopants, and particularly boron, can diffuse from gate 140 into substrate 130 and vice versa, or be trapped in oxide 140, degrading the transistor's electrical characteristics. See U.S. Pat. No. 5,939,763 issued on Aug. 17, 1999 to Hao et al. and incorporated herein by reference. Therefore, oxide 140 is sometimes nitrided to block the dopant diffusion. Nitrogen however can also cause degradation of the transistor's performance (due to an increased oxide charge for example). Therefore, high nitrogen concentrations are avoided except near polysilicon 150 (in sub-region 140t of oxide 140) and near substrate 130 (in sub-region 140i). The nitrogen concentration thus has a double peak structure. One peak is located in a sub-region 140t, and the other peak in sub-region 140i. The oxide region 140b (“oxide bulk”) between the regions 140t, 140i has a low nitrogen concentration.

The double peak structure can be obtained as follows. First, layer 140 is formed of pure silicon dioxide. Then layer 140 is nitrided using remote plasma nitridation (RPN) or decoupled plasma nitridation (DPN). RPN and DPN are described in U.S. Patent Application published as no. 2004/0185647 on Sep. 23, 2004, filed by Zhong Dong et al., entitled “Floating Gate Nitridation”, incorporated herein by reference. The plasma nitridation is followed by a thermal anneal. The anneal and subsequent thermal processing disadvantageously cause some of the nitrogen to diffuse from regions 140t, 140i into oxide bulk 140b.

Plasma nitridation can be replaced by an anneal in the presence of ammonia (NH₃), or by heating the wafer in nitric oxide (NO). These steps can be followed by additional oxidation. See the aforementioned U.S. Pat. No. 5,939,763.

### SUMMARY

This section summarizes some features of the invention. Other features are described in the subsequent sections. The invention is defined by the appended claims which are incorporated into this section by reference.

In some embodiments of the present invention, a nitrided silicon oxide layer is formed on the silicon substrate's surface, possibly by prior art techniques, to provide a high nitrogen concentration near the substrate/oxide interface. Then a portion of the silicon oxide layer is etched away, leaving a thin layer of nitrided silicon oxide with a high nitrogen concentration. Then an oxidation step is performed (e.g. Rapid Thermal Oxidation, or RTO) to oxidize some of the silicon below the silicon oxide layer. Much of the nitrogen remains near the top surface of the silicon oxide layer, thus providing a sharp peak at the top surface (the top surface will be located near the polysilicon when the polysilicon is deposited). The high RTO temperature (1000-1100° C. in some embodiments) serves to bind the nitrogen with the silicon and oxygen atoms. Consequently, the nitrogen diffusion will be minimal in subsequent steps, insuring a high nitrogen concentration near the polysilicon and a low nitrogen concentration in the oxide bulk.

If desired, additional nitridation is performed (e.g. thermal nitridation) to increase the nitridation concentration near the silicon substrate. This nitridation step can be performed by prior art techniques. Nitrogen provided by a gaseous source (e.g. NO or N₂O) will diffuse towards the substrate/oxide interface. The nitridation temperature is below the RTO temperature of the oxidation step in order to minimize disturbance of the nitrogen atoms present at the top surface during the RTO.

The invention is not limited to the embodiments described above. In some embodiments, a nitrogen containing layer is formed on a silicon containing region. Then a portion of the nitrogen containing layer is removed. Then thermal oxidation is performed. The invention is not limited to polysilicon or monocrystalline silicon. The invention can be used in non-volatile memories to form dielectric separating floating gates from control gates, select gates, and/or other elements of integrated circuits. The control and select gates can be formed side by side with the floating gates (rather than one on top of another). The MOS gates, the floating gates, and other elements do not have to be formed above the channel regions but can be formed in trenches or with other geometry, known or to be invented. The invention is not limited to the features or advantages described above. Other features are described below. The invention is defined by the appended claims.

### BRIEF DESCRIPTION OF THE DRAWINGS

FIG. 1 illustrates a vertical cross section of a prior art MOS transistor.

FIGS. 2, 3A illustrate vertical cross sections of a semiconductor structure in the process of fabrication according to some embodiments of the present invention.

FIG. 3B is a graph of silicon, oxygen and nitrogen concentrations in some embodiments of the structure of FIG. 3A.

FIGS. 4, 5A illustrate vertical cross sections of a semiconductor structure in the process of fabrication according to some embodiments of the present invention.

FIGS. 5B, 5C are graphs of silicon, oxygen and nitrogen concentrations in some embodiments of the structure of FIG. 5A.

FIG. 6 illustrates a vertical cross section of a semiconductor structure in the process of fabrication according to some embodiments of the present invention.

### DESCRIPTION OF SOME EMBODIMENTS

The embodiments described in this section illustrate but do not limit the invention. Dimensions, process parameters, and other details are given for illustration and not to limit the invention. The invention is defined by the appended claims.

FIG. 2 shows the beginning stages of nitrided silicon oxide fabrication in some embodiments of the present invention. Silicon region 130 can be a doped or undoped monocrystalline silicon wafer. The wafer can be a bare wafer, or the wafer may contain field dielectric or other elements as known in the art. Silicon oxide 210 is formed on the wafer by thermal oxidation, chemical vapor deposition (CVD), or some other techniques. In some embodiments, oxide 210 is pure oxide, free of nitrogen or other elements. An exemplary thickness of oxide 210 is 1˜3 nm.

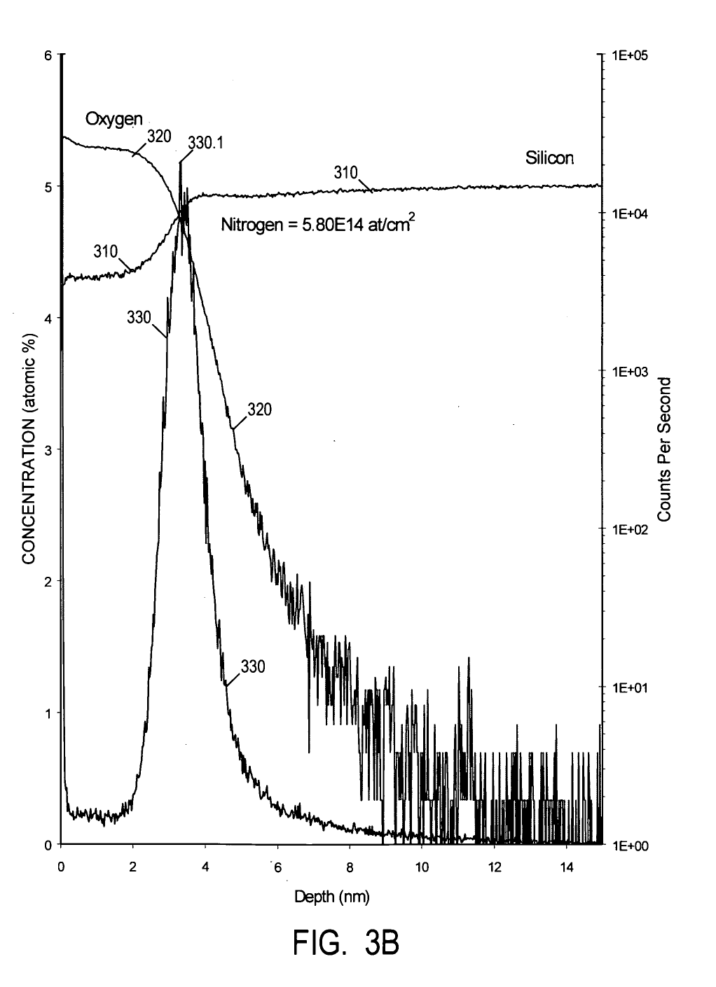

Thermal nitridation of oxide 210 results in formation of a nitrided silicon oxide layer 210N (FIG. 3A) at the bottom of layer 210, adjacent to silicon substrate 130. In some embodiments, the thermal nitridation is performed by holding the wafer in a furnace at 800°˜950° C. for 5˜30 minutes in the presence of NO or NH₃, using known techniques. The resulting nitrogen, oxygen and silicon concentrations are shown in FIG. 3B in atomic percents. The horizontal axis in FIG. 3B shows the depth, i.e. the distance from the top surface of oxide 210. Curve 310 shows the silicon concentration, curve 320 shows the oxygen concentration, and curve 330 show the nitrogen concentration. The oxide thickness is about 4 nm, as indicated by the decreasing concentration of oxygen and the increasing concentration of silicon. The peak nitrogen concentration is achieved at the depth of about 3.1 nm as shown at 330.1. The peak concentration is about 5.2 atomic percent, or about 5.80×10¹⁴ atoms/cm². In other embodiments, peak nitrogen concentrations of 2-8% (atomic) are obtained using thermal nitridation with nitric oxide (NO). The concentrations of 3-8% (atomic) are obtained with NH₃. Other concentrations are also possible.

For simplicity, FIG. 3A shows a sharp boundary between high nitrogen concentration region 210N and the rest of oxide 210, but the nitrogen concentration can change gradually as illustrated in FIG. 3B.

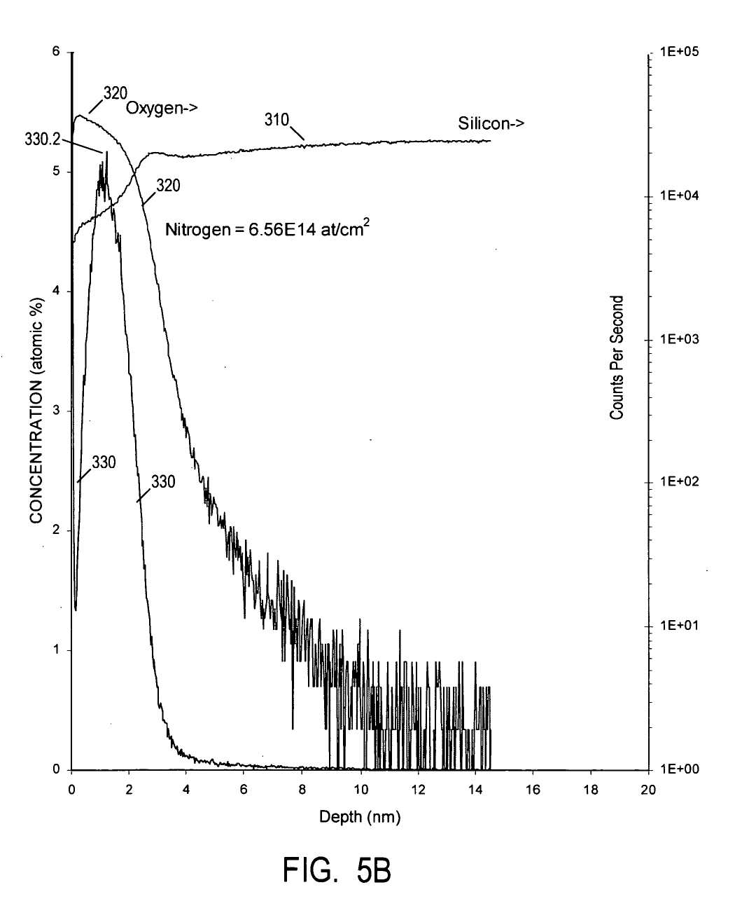

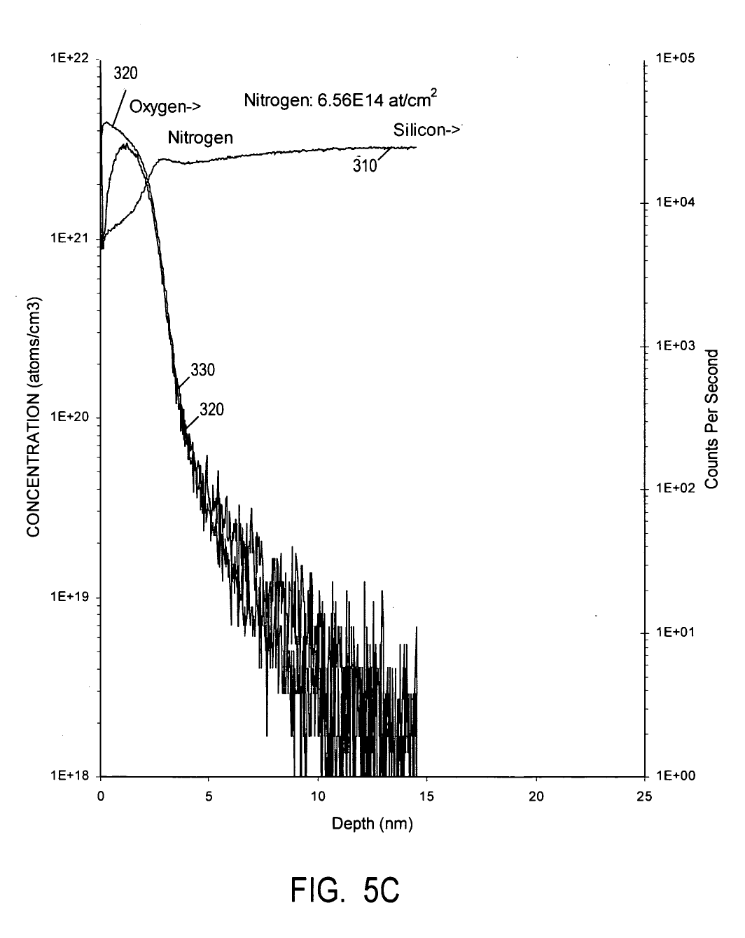

Comment on the charts of FIGS. 3B, 5B, 5C: These charts were obtained by Secondary Ion Mass Spectrometry (SIMS). The SIMS data may contain an artifact. Also, the software used to construct the charts from the measured data did not allow plotting zero on a logarithmic axis. That software also excluded any real non-zero data points flanked by two zeros. Therefore, RAW data points that were originally 0 were replaced by 0.3 prior to the concentration calculation.

The thermal nitridation of oxide 210 can be replaced by plasma nitridation.

Then oxide 210 is partially etched down (FIG. 4), to an exemplary thickness of 0.3˜1 nm. A suitable etch is with diluted HF at 20° C. The dilution ratio can be about 100:1. The diluted HF etch rate of pure silicon dioxide is higher than the etch rate of nitrided silicon dioxide, so the etch can be stopped before complete removal of the nitrogen rich layer 210N.

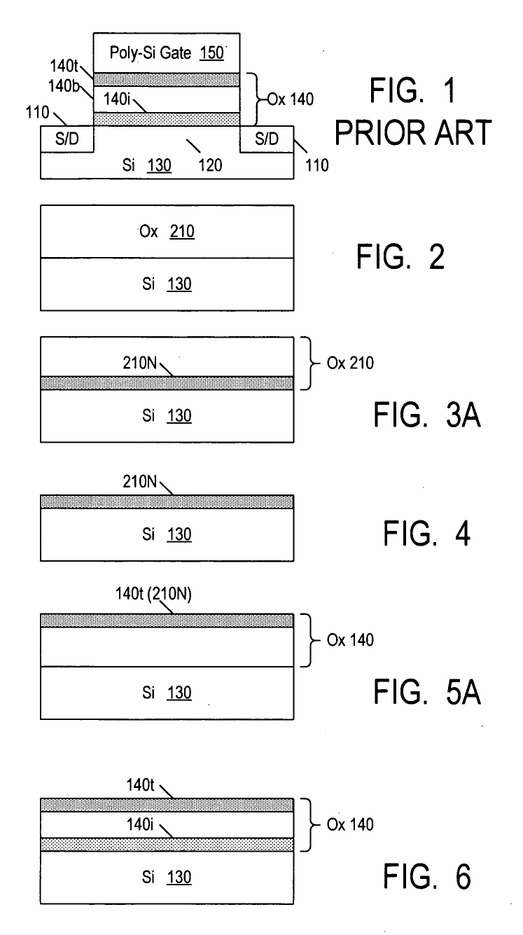

The wafer is heated in an oxygen containing atmosphere to grow silicon oxide under the layer 210N. See FIG. 5A. This silicon oxide and the layer 210N form silicon oxide layer 140 on silicon substrate 130. In some embodiments, this step is performed by Rapid Thermal Oxidation (RTO) in a furnace at 1000-1100° C. for 5-200 seconds in dry, oxygen containing atmosphere. The atmosphere is nitrogen-free in some embodiments. Oxygen atoms penetrate the layer 210N (FIG. 4) to react with the silicon of substrate 310. The nitrogen atoms of layer 210N remain largely at the top surface of the structure, providing the top nitrided region 140t (FIGS. 5A, 1). An exemplary thickness of oxide layer 140 is 1˜5 nm.

FIGS. 5B, 5C show the nitrogen concentration (curve 330), the oxygen concentration (curve 320), and the silicon concentration (curve 310) in one embodiment in which the thickness of oxide 140 is about 3.0 nm. FIG. 5B shows the concentrations in atomic percent, and FIG. 5C in atoms/cm³. Table 1 below shows the concentrations numerically for FIG. 5B, and Table 2 shows the concentrations numerically for FIG. 5C. The depth is measured from the top of oxide 140. The peak nitrogen concentration is achieved at the depth of about 1 nm as shown at 330.2 in FIG. 5B. The peak concentration is about 5.2 atomic percent, or about 6.56×10¹⁴ atoms/cm². Other concentrations are also possible. The nitrogen concentration becomes less than 0.2% at the depth of 4 nm and remains below 0.2% at larger depths in the oxide bulk.

If desired, oxide 140 can be nitrided to increase the nitrogen concentration in a sub-region 140i (FIG. 6) of oxide 140 adjacent to silicon 130. In some embodiments, layer 140i is formed by thermal nitridation in N₂O or NO at 900-1050° C. for 10-200 seconds. An exemplary thickness of layer 140i is 0.3˜1 nm. In some embodiments, the thickness of each of layers 140t, 140i is at most about ⅓ (about 33.3%) of the total thickness of oxide 140. In the nitridation process, the nitrogen atoms penetrate the oxide 140 and reach silicon 130. In some embodiments, the nitridation temperature is below the RTO temperature used to create the structure of FIG. 5A. Therefore, the nitrogen atoms bound with silicon and oxygen in layer 140t at the stage of FIG. 5A are unlikely to leave the layer 140t during the thermal nitridation. The nitrogen concentration in layer 140t and between the layers 140t, 140i is therefore likely to remain substantially as in FIGS. 5B, 5C. The nitrogen concentration in layer 140i is about 2% in some embodiments, and other concentrations can also be achieved. The thermal nitridation is replaced with plasma nitridation in some embodiments.

The fabrication can be completed with known techniques. For example, polysilicon 150 (FIG. 1) can be deposited and patterned to form a transistor gate. Regions 110, 120 can be formed by doping at any suitable fabrication stage. In some embodiments, one or more of regions 110, 120, 150 include boron doping.

The invention is not limited to the embodiments described above. The invention is not limited to polysilicon or monocrystalline silicon, or to any dimensions, concentrations or doping levels. The invention is not limited to the data shown in the figures or in the tables. Other embodiments and variations are within the scope of the invention, as defined by the appended claims.

TABLE 1

| | | | | | Nitrogen = |
|---|---|---|---|---|---|
| Depth | | Depth | | Depth | 6.56E14 |
| (nm) | Silicon | (nm) | Oxygen | (nm) | at/cm2 |
| 8.91E−03 | 9.00E+03 | 3.12E−02 | 2.65E+04 | 2.23E−02 | 1.59E+01 |
| 3.92E−02 | 4.92E+03 | 6.15E−02 | 2.91E+04 | 5.26E−02 | 4.43E+00 |
| 7.04E−02 | 4.74E+03 | 9.18E−02 | 3.22E+04 | 8.29E−02 | 2.01E+00 |
| 1.01E−01 | 4.87E+03 | 1.23E−01 | 3.41E+04 | 1.14E−01 | 1.37E+00 |
| 1.31E−01 | 5.24E+03 | 1.53E−01 | 3.54E+04 | 1.44E−01 | 1.33E+00 |
| 1.62E−01 | 5.48E+03 | 1.84E−01 | 3.58E+04 | 1.75E−01 | 1.58E+00 |
| 1.93E−01 | 5.46E+03 | 2.14E−01 | 3.63E+04 | 2.06E−01 | 1.67E+00 |
| 2.23E−01 | 5.81E+03 | 2.45E−01 | 3.60E+04 | 2.36E−01 | 1.94E+00 |
| 2.54E−01 | 6.04E+03 | 2.75E−01 | 3.68E+04 | 2.67E−01 | 2.09E+00 |
| 2.84E−01 | 6.06E+03 | 3.06E−01 | 3.64E+04 | 2.98E−01 | 2.46E+00 |
| 3.15E−01 | 6.09E+03 | 3.37E−01 | 3.61E+04 | 3.28E−01 | 2.68E+00 |
| 3.45E−01 | 6.09E+03 | 3.67E−01 | 3.61E+04 | 3.58E−01 | 2.79E+00 |
| 3.76E−01 | 6.53E+03 | 3.98E−01 | 3.56E+04 | 3.89E−01 | 2.99E+00 |
| 4.06E−01 | 6.42E+03 | 4.29E−01 | 3.55E+04 | 4.20E−01 | 3.31E+00 |
| 4.37E−01 | 6.36E+03 | 4.59E−01 | 3.50E+04 | 4.50E−01 | 3.22E+00 |
| 4.68E−01 | 6.31E+03 | 4.89E−01 | 3.48E+04 | 4.80E−01 | 3.39E+00 |
| 4.98E−01 | 6.57E+03 | 5.20E−01 | 3.49E+04 | 5.12E−01 | 3.57E+00 |
| 5.29E−01 | 6.59E+03 | 5.51E−01 | 3.37E+04 | 5.42E−01 | 3.63E+00 |
| 5.60E−01 | 6.69E+03 | 5.81E−01 | 3.37E+04 | 5.72E−01 | 3.81E+00 |
| 5.90E−01 | 6.74E+03 | 6.12E−01 | 3.33E+04 | 6.04E−01 | 4.03E+00 |
| 6.20E−01 | 6.69E+03 | 6.43E−01 | 3.34E+04 | 6.34E−01 | 4.08E+00 |
| 6.52E−01 | 6.66E+03 | 6.73E−01 | 3.32E+04 | 6.64E−01 | 4.23E+00 |
| 6.82E−01 | 7.00E+03 | 7.03E−01 | 3.34E+04 | 6.94E−01 | 4.16E+00 |
| 7.12E−01 | 7.08E+03 | 7.35E−01 | 3.24E+04 | 7.26E−01 | 4.48E+00 |
| 7.43E−01 | 6.94E+03 | 7.65E−01 | 3.23E+04 | 7.56E−01 | 4.47E+00 |
| 7.74E−01 | 7.17E+03 | 7.95E−01 | 3.22E+04 | 7.86E−01 | 4.51E+00 |
| 8.04E−01 | 7.08E+03 | 8.26E−01 | 3.23E+04 | 8.17E−01 | 4.54E+00 |
| 8.34E−01 | 7.08E+03 | 8.57E−01 | 3.18E+04 | 8.48E−01 | 4.68E+00 |
| 8.66E−01 | 7.19E+03 | 8.87E−01 | 3.13E+04 | 8.78E−01 | 4.85E+00 |
| 8.96E−01 | 7.16E+03 | 9.17E−01 | 3.17E+04 | 9.09E−01 | 4.86E+00 |
| 9.26E−01 | 7.40E+03 | 9.48E−01 | 3.07E+04 | 9.40E−01 | 4.93E+00 |
| 9.57E−01 | 7.40E+03 | 9.79E−01 | 3.02E+04 | 9.70E−01 | 4.80E+00 |
| 9.88E−01 | 7.27E+03 | 1.01E+00 | 3.05E+04 | 1.00E+00 | 5.06E+00 |
| 1.02E+00 | 7.68E+03 | 1.04E+00 | 3.06E+04 | 1.03E+00 | 4.87E+00 |
| 1.05E+00 | 7.54E+03 | 1.07E+00 | 2.96E+04 | 1.06E+00 | 5.09E+00 |
| 1.08E+00 | 7.78E+03 | 1.10E+00 | 2.94E+04 | 1.09E+00 | 4.84E+00 |
| 1.11E+00 | 7.85E+03 | 1.13E+00 | 2.93E+04 | 1.12E+00 | 4.96E+00 |
| 1.14E+00 | 7.75E+03 | 1.16E+00 | 2.88E+04 | 1.15E+00 | 4.75E+00 |
| 1.17E+00 | 7.89E+03 | 1.19E+00 | 2.84E+04 | 1.18E+00 | 4.96E+00 |
| 1.20E+00 | 8.02E+03 | 1.22E+00 | 2.79E+04 | 1.22E+00 | 5.17E+00 |
| 1.23E+00 | 8.14E+03 | 1.25E+00 | 2.81E+04 | 1.25E+00 | 4.91E+00 |
| 1.26E+00 | 8.19E+03 | 1.28E+00 | 2.73E+04 | 1.28E+00 | 4.88E+00 |
| 1.29E+00 | 8.23E+03 | 1.31E+00 | 2.73E+04 | 1.31E+00 | 4.77E+00 |
| 1.32E+00 | 8.31E+03 | 1.35E+00 | 2.72E+04 | 1.34E+00 | 4.79E+00 |
| 1.35E+00 | 8.51E+03 | 1.38E+00 | 2.63E+04 | 1.37E+00 | 4.77E+00 |
| 1.39E+00 | 8.57E+03 | 1.41E+00 | 2.62E+04 | 1.40E+00 | 4.67E+00 |
| 1.42E+00 | 8.77E+03 | 1.44E+00 | 2.57E+04 | 1.43E+00 | 4.60E+00 |
| 1.45E+00 | 8.56E+03 | 1.47E+00 | 2.57E+04 | 1.46E+00 | 4.70E+00 |
| 1.48E+00 | 8.72E+03 | 1.50E+00 | 2.50E+04 | 1.49E+00 | 4.64E+00 |
| 1.51E+00 | 8.80E+03 | 1.53E+00 | 2.50E+04 | 1.52E+00 | 4.49E+00 |
| 1.54E+00 | 8.97E+03 | 1.56E+00 | 2.46E+04 | 1.55E+00 | 4.40E+00 |
| 1.57E+00 | 9.03E+03 | 1.59E+00 | 2.36E+04 | 1.58E+00 | 4.42E+00 |
| 1.60E+00 | 9.27E+03 | 1.62E+00 | 2.32E+04 | 1.61E+00 | 4.49E+00 |
| 1.63E+00 | 9.59E+03 | 1.65E+00 | 2.35E+04 | 1.64E+00 | 4.34E+00 |
| 1.66E+00 | 9.87E+03 | 1.68E+00 | 2.30E+04 | 1.67E+00 | 4.34E+00 |
| 1.69E+00 | 1.01E+04 | 1.71E+00 | 2.25E+04 | 1.70E+00 | 4.48E+00 |
| 1.72E+00 | 9.88E+03 | 1.74E+00 | 2.20E+04 | 1.73E+00 | 4.14E+00 |
| 1.75E+00 | 1.02E+04 | 1.77E+00 | 2.16E+04 | 1.77E+00 | 4.01E+00 |
| 1.78E+00 | 1.05E+04 | 1.80E+00 | 2.09E+04 | 1.80E+00 | 3.98E+00 |
| 1.81E+00 | 1.06E+04 | 1.84E+00 | 2.06E+04 | 1.83E+00 | 3.85E+00 |
| 1.84E+00 | 1.08E+04 | 1.87E+00 | 2.01E+04 | 1.86E+00 | 3.81E+00 |
| 1.87E+00 | 1.13E+04 | 1.90E+00 | 1.94E+04 | 1.89E+00 | 3.64E+00 |
| 1.91E+00 | 1.16E+04 | 1.93E+00 | 1.90E+04 | 1.92E+00 | 3.64E+00 |
| 1.94E+00 | 1.19E+04 | 1.96E+00 | 1.85E+04 | 1.95E+00 | 3.54E+00 |
| 1.97E+00 | 1.19E+04 | 1.99E+00 | 1.79E+04 | 1.98E+00 | 3.48E+00 |
| 2.00E+00 | 1.18E+04 | 2.02E+00 | 1.71E+04 | 2.01E+00 | 3.33E+00 |
| 2.03E+00 | 1.24E+04 | 2.05E+00 | 1.66E+04 | 2.04E+00 | 3.31E+00 |
| 2.06E+00 | 1.28E+04 | 2.08E+00 | 1.65E+04 | 2.07E+00 | 3.29E+00 |
| 2.09E+00 | 1.29E+04 | 2.11E+00 | 1.59E+04 | 2.10E+00 | 3.10E+00 |
| 2.12E+00 | 1.38E+04 | 2.14E+00 | 1.51E+04 | 2.13E+00 | 3.02E+00 |
| 2.15E+00 | 1.40E+04 | 2.17E+00 | 1.45E+04 | 2.16E+00 | 2.99E+00 |
| 2.18E+00 | 1.42E+04 | 2.20E+00 | 1.41E+04 | 2.19E+00 | 2.79E+00 |
| 2.21E+00 | 1.46E+04 | 2.23E+00 | 1.38E+04 | 2.22E+00 | 2.81E+00 |
| 2.24E+00 | 1.51E+04 | 2.26E+00 | 1.28E+04 | 2.25E+00 | 2.54E+00 |
| 2.27E+00 | 1.57E+04 | 2.29E+00 | 1.21E+04 | 2.28E+00 | 2.53E+00 |
| 2.30E+00 | 1.57E+04 | 2.32E+00 | 1.17E+04 | 2.32E+00 | 2.46E+00 |
| 2.33E+00 | 1.59E+04 | 2.36E+00 | 1.12E+04 | 2.35E+00 | 2.48E+00 |
| 2.36E+00 | 1.65E+04 | 2.39E+00 | 1.05E+04 | 2.38E+00 | 2.29E+00 |
| 2.39E+00 | 1.70E+04 | 2.42E+00 | 9.83E+03 | 2.41E+00 | 2.18E+00 |
| 2.42E+00 | 1.76E+04 | 2.45E+00 | 9.63E+03 | 2.44E+00 | 2.07E+00 |
| 2.46E+00 | 1.78E+04 | 2.48E+00 | 8.72E+03 | 2.47E+00 | 1.87E+00 |
| 2.49E+00 | 1.82E+04 | 2.51E+00 | 8.21E+03 | 2.50E+00 | 1.92E+00 |
| 2.52E+00 | 1.85E+04 | 2.54E+00 | 7.79E+03 | 2.53E+00 | 1.68E+00 |
| 2.55E+00 | 1.84E+04 | 2.57E+00 | 7.21E+03 | 2.56E+00 | 1.72E+00 |
| 2.58E+00 | 1.86E+04 | 2.60E+00 | 6.81E+03 | 2.59E+00 | 1.60E+00 |
| 2.61E+00 | 1.91E+04 | 2.63E+00 | 6.33E+03 | 2.62E+00 | 1.44E+00 |
| 2.64E+00 | 1.91E+04 | 2.66E+00 | 5.89E+03 | 2.65E+00 | 1.41E+00 |
| 2.67E+00 | 1.93E+04 | 2.69E+00 | 5.65E+03 | 2.68E+00 | 1.33E+00 |
| 2.70E+00 | 2.00E+04 | 2.72E+00 | 5.17E+03 | 2.71E+00 | 1.25E+00 |
| 2.73E+00 | 1.97E+04 | 2.75E+00 | 4.71E+03 | 2.74E+00 | 1.24E+00 |
| 2.76E+00 | 1.98E+04 | 2.78E+00 | 4.33E+03 | 2.77E+00 | 1.05E+00 |
| 2.79E+00 | 2.02E+04 | 2.81E+00 | 4.05E+03 | 2.80E+00 | 1.12E+00 |
| 2.82E+00 | 2.00E+04 | 2.84E+00 | 3.63E+03 | 2.84E+00 | 9.34E−01 |
| 2.85E+00 | 2.03E+04 | 2.87E+00 | 3.45E+03 | 2.87E+00 | 8.43E−01 |
| 2.88E+00 | 2.03E+04 | 2.91E+00 | 3.26E+03 | 2.90E+00 | 9.29E−01 |
| 2.91E+00 | 2.02E+04 | 2.94E+00 | 2.89E+03 | 2.93E+00 | 8.09E−01 |
| 2.94E+00 | 2.00E+04 | 2.97E+00 | 2.65E+03 | 2.96E+00 | 7.80E−01 |
| 2.98E+00 | 2.00E+04 | 3.00E+00 | 2.45E+03 | 2.99E+00 | 6.89E−01 |
| 3.01E+00 | 2.02E+04 | 3.03E+00 | 2.43E+03 | 3.02E+00 | 6.93E−01 |
| 3.04E+00 | 2.01E+04 | 3.06E+00 | 2.12E+03 | 3.05E+00 | 5.55E−01 |
| 3.07E+00 | 1.97E+04 | 3.09E+00 | 1.94E+03 | 3.08E+00 | 5.13E−01 |
| 3.10E+00 | 1.97E+04 | 3.12E+00 | 1.72E+03 | 3.11E+00 | 5.59E−01 |
| 3.13E+00 | 2.01E+04 | 3.15E+00 | 1.65E+03 | 3.14E+00 | 5.24E−01 |
| 3.16E+00 | 1.98E+04 | 3.18E+00 | 1.45E+03 | 3.17E+00 | 4.89E−01 |
| 3.19E+00 | 2.00E+04 | 3.21E+00 | 1.32E+03 | 3.20E+00 | 4.16E−01 |
| 3.22E+00 | 1.98E+04 | 3.24E+00 | 1.15E+03 | 3.23E+00 | 4.20E−01 |
| 3.25E+00 | 1.99E+04 | 3.27E+00 | 1.20E+03 | 3.26E+00 | 3.91E−01 |
| 3.28E+00 | 1.96E+04 | 3.30E+00 | 1.11E+03 | 3.29E+00 | 3.91E−01 |
| 3.31E+00 | 1.94E+04 | 3.33E+00 | 1.01E+03 | 3.33E+00 | 3.87E−01 |
| 3.34E+00 | 1.94E+04 | 3.36E+00 | 9.33E+02 | 3.36E+00 | 2.71E−01 |
| 3.37E+00 | 1.93E+04 | 3.39E+00 | 7.80E+02 | 3.39E+00 | 3.50E−01 |
| 3.40E+00 | 1.96E+04 | 3.42E+00 | 7.48E+02 | 3.42E+00 | 2.57E−01 |
| 3.43E+00 | 1.96E+04 | 3.46E+00 | 6.87E+02 | 3.45E+00 | 2.63E−01 |
| 3.46E+00 | 1.92E+04 | 3.49E+00 | 6.18E+02 | 3.48E+00 | 2.86E−01 |
| 3.50E+00 | 1.93E+04 | 3.52E+00 | 5.68E+02 | 3.51E+00 | 1.82E−01 |
| 3.53E+00 | 1.91E+04 | 3.55E+00 | 5.46E+02 | 3.54E+00 | 2.53E−01 |
| 3.56E+00 | 1.91E+04 | 3.58E+00 | 5.67E+02 | 3.57E+00 | 2.21E−01 |
| 3.59E+00 | 1.91E+04 | 3.61E+00 | 5.19E+02 | 3.60E+00 | 1.90E−01 |
| 3.62E+00 | 1.93E+04 | 3.64E+00 | 5.26E+02 | 3.63E+00 | 1.70E−01 |
| 3.65E+00 | 1.93E+04 | 3.67E+00 | 4.48E+02 | 3.66E+00 | 1.70E−01 |
| 3.68E+00 | 1.90E+04 | 3.70E+00 | 4.67E+02 | 3.69E+00 | 2.01E−01 |
| 3.71E+00 | 1.90E+04 | 3.73E+00 | 4.01E+02 | 3.72E+00 | 1.28E−01 |
| 3.74E+00 | 1.89E+04 | 3.76E+00 | 3.85E+02 | 3.75E+00 | 1.41E−01 |
| 3.77E+00 | 1.90E+04 | 3.79E+00 | 3.34E+02 | 3.78E+00 | 1.66E−01 |
| 3.80E+00 | 1.89E+04 | 3.82E+00 | 3.34E+02 | 3.81E+00 | 1.22E−01 |
| 3.83E+00 | 1.87E+04 | 3.85E+00 | 2.73E+02 | 3.84E+00 | 1.70E−01 |
| 3.86E+00 | 1.92E+04 | 3.88E+00 | 3.07E+02 | 3.88E+00 | 1.14E−01 |
| 3.89E+00 | 1.85E+04 | 3.91E+00 | 2.42E+02 | 3.91E+00 | 1.47E−01 |
| 3.92E+00 | 1.87E+04 | 3.94E+00 | 2.86E+02 | 3.94E+00 | 1.06E−01 |
| 3.95E+00 | 1.87E+04 | 3.98E+00 | 2.29E+02 | 3.97E+00 | 1.14E−01 |
| 3.98E+00 | 1.88E+04 | 4.01E+00 | 2.08E+02 | 4.00E+00 | 1.16E−01 |
| 4.02E+00 | 1.92E+04 | 4.04E+00 | 2.46E+02 | 4.03E+00 | 1.22E−01 |
| 4.05E+00 | 1.87E+04 | 4.07E+00 | 2.27E+02 | 4.06E+00 | 9.94E−02 |
| 4.08E+00 | 1.93E+04 | 4.10E+00 | 2.10E+02 | 4.09E+00 | 8.90E−02 |
| 4.11E+00 | 1.90E+04 | 4.13E+00 | 1.62E+02 | 4.12E+00 | 1.24E−01 |
| 4.14E+00 | 1.89E+04 | 4.16E+00 | 1.68E+02 | 4.15E+00 | 1.12E−01 |
| 4.17E+00 | 1.89E+04 | 4.19E+00 | 1.51E+02 | 4.18E+00 | 9.94E−02 |
| 4.20E+00 | 1.91E+04 | 4.22E+00 | 1.51E+02 | 4.21E+00 | 1.06E−01 |
| 4.23E+00 | 1.91E+04 | 4.25E+00 | 1.75E+02 | 4.24E+00 | 1.01E−01 |
| 4.26E+00 | 1.89E+04 | 4.28E+00 | 1.24E+02 | 4.27E+00 | 1.12E−01 |
| 4.29E+00 | 1.92E+04 | 4.31E+00 | 1.47E+02 | 4.30E+00 | 5.80E−02 |
| 4.32E+00 | 1.90E+04 | 4.34E+00 | 1.43E+02 | 4.33E+00 | 9.73E−02 |
| 4.35E+00 | 1.91E+04 | 4.37E+00 | 1.37E+02 | 4.36E+00 | 7.87E−02 |
| 4.38E+00 | 1.90E+04 | 4.40E+00 | 1.34E+02 | 4.39E+00 | 8.69E−02 |
| 4.41E+00 | 1.91E+04 | 4.43E+00 | 1.13E+02 | 4.43E+00 | 7.66E−02 |
| 4.44E+00 | 1.90E+04 | 4.47E+00 | 1.05E+02 | 4.46E+00 | 5.38E−02 |
| 4.47E+00 | 1.96E+04 | 4.50E+00 | 1.01E+02 | 4.49E+00 | 7.87E−02 |
| 4.50E+00 | 1.93E+04 | 4.53E+00 | 1.01E+02 | 4.52E+00 | 8.69E−02 |
| 4.53E+00 | 1.92E+04 | 4.56E+00 | 1.13E+02 | 4.55E+00 | 7.87E−02 |
| 4.57E+00 | 1.91E+04 | 4.59E+00 | 1.07E+02 | 4.58E+00 | 6.42E−02 |
| 4.60E+00 | 1.94E+04 | 4.62E+00 | 9.92E+01 | 4.61E+00 | 7.04E−02 |
| 4.63E+00 | 1.95E+04 | 4.65E+00 | 7.25E+01 | 4.64E+00 | 8.28E−02 |
| 4.66E+00 | 1.93E+04 | 4.68E+00 | 9.16E+01 | 4.67E+00 | 5.38E−02 |
| 4.69E+00 | 1.94E+04 | 4.71E+00 | 6.87E+01 | 4.70E+00 | 7.04E−02 |
| 4.72E+00 | 1.95E+04 | 4.74E+00 | 7.44E+01 | 4.73E+00 | 7.45E−02 |
| 4.75E+00 | 1.90E+04 | 4.77E+00 | 1.11E+02 | 4.76E+00 | 6.62E−02 |
| 4.78E+00 | 1.94E+04 | 4.80E+00 | 5.15E+01 | 4.79E+00 | 5.38E−02 |
| 4.81E+00 | 1.93E+04 | 4.83E+00 | 8.39E+01 | 4.82E+00 | 4.97E−02 |
| 4.84E+00 | 1.96E+04 | 4.86E+00 | 6.87E+01 | 4.85E+00 | 7.66E−02 |
| 4.87E+00 | 1.94E+04 | 4.89E+00 | 5.91E+01 | 4.88E+00 | 8.07E−02 |
| 4.90E+00 | 1.95E+04 | 4.92E+00 | 6.68E+01 | 4.91E+00 | 9.32E−02 |
| 4.93E+00 | 1.96E+04 | 4.95E+00 | 8.01E+01 | 4.95E+00 | 6.42E−02 |
| 4.96E+00 | 1.95E+04 | 4.98E+00 | 7.25E+01 | 4.98E+00 | 5.80E−02 |
| 4.99E+00 | 1.93E+04 | 5.02E+00 | 7.06E+01 | 5.01E+00 | 4.97E−02 |
| 5.02E+00 | 1.95E+04 | 5.05E+00 | 6.87E+01 | 5.04E+00 | 5.38E−02 |
| 5.05E+00 | 1.99E+04 | 5.08E+00 | 6.68E+01 | 5.07E+00 | 4.35E−02 |
| 5.09E+00 | 1.99E+04 | 5.11E+00 | 4.96E+01 | 5.10E+00 | 3.11E−02 |
| 5.12E+00 | 1.96E+04 | 5.14E+00 | 5.15E+01 | 5.13E+00 | 4.55E−02 |
| 5.15E+00 | 2.03E+04 | 5.17E+00 | 5.72E+01 | 5.16E+00 | 4.76E−02 |
| 5.18E+00 | 2.00E+04 | 5.20E+00 | 5.91E+01 | 5.19E+00 | 6.42E−02 |
| 5.21E+00 | 1.98E+04 | 5.23E+00 | 4.77E+01 | 5.22E+00 | 4.97E−02 |
| 5.24E+00 | 1.99E+04 | 5.26E+00 | 5.53E+01 | 5.25E+00 | 4.55E−02 |
| 5.27E+00 | 2.00E+04 | 5.29E+00 | 4.77E+01 | 5.28E+00 | 5.18E−02 |
| 5.30E+00 | 2.01E+04 | 5.32E+00 | 6.29E+01 | 5.31E+00 | 4.76E−02 |
| 5.33E+00 | 2.01E+04 | 5.35E+00 | 5.91E+01 | 5.34E+00 | 5.38E−02 |
| 5.36E+00 | 2.04E+04 | 5.38E+00 | 4.39E+01 | 5.37E+00 | 3.93E−02 |
| 5.39E+00 | 1.98E+04 | 5.41E+00 | 3.05E+01 | 5.40E+00 | 4.97E−02 |
| 5.42E+00 | 2.02E+04 | 5.44E+00 | 4.20E+01 | 5.43E+00 | 7.66E−02 |
| 5.45E+00 | 2.04E+04 | 5.47E+00 | 4.58E+01 | 5.47E+00 | 2.90E−02 |
| 5.48E+00 | 2.03E+04 | 5.50E+00 | 2.86E+01 | 5.50E+00 | 5.38E−02 |
| 5.51E+00 | 2.03E+04 | 5.53E+00 | 4.96E+01 | 5.53E+00 | 2.90E−02 |
| 5.54E+00 | 2.03E+04 | 5.57E+00 | 4.77E+01 | 5.56E+00 | 4.97E−02 |
| 5.57E+00 | 2.03E+04 | 5.60E+00 | 3.43E+01 | 5.59E+00 | 4.97E−02 |
| 5.61E+00 | 2.04E+04 | 5.63E+00 | 2.29E+01 | 5.62E+00 | 3.52E−02 |
| 5.64E+00 | 2.06E+04 | 5.66E+00 | 4.96E+01 | 5.65E+00 | 4.14E−02 |
| 5.67E+00 | 2.05E+04 | 5.69E+00 | 3.62E+01 | 5.68E+00 | 3.73E−02 |
| 5.70E+00 | 2.01E+04 | 5.72E+00 | 3.05E+01 | 5.71E+00 | 4.14E−02 |
| 5.73E+00 | 2.01E+04 | 5.75E+00 | 4.58E+01 | 5.74E+00 | 3.93E−02 |
| 5.76E+00 | 2.02E+04 | 5.78E+00 | 2.86E+01 | 5.77E+00 | 5.38E−02 |
| 5.79E+00 | 2.03E+04 | 5.81E+00 | 4.01E+01 | 5.80E+00 | 5.18E−02 |
| 5.82E+00 | 2.02E+04 | 5.84E+00 | 3.05E+01 | 5.83E+00 | 5.59E−02 |
| 5.85E+00 | 2.06E+04 | 5.87E+00 | 3.62E+01 | 5.86E+00 | 3.31E−02 |
| 5.88E+00 | 2.11E+04 | 5.90E+00 | 2.48E+01 | 5.89E+00 | 3.11E−02 |
| 5.91E+00 | 2.11E+04 | 5.93E+00 | 3.24E+01 | 5.92E+00 | 3.31E−02 |
| 5.94E+00 | 2.03E+04 | 5.96E+00 | 2.67E+01 | 5.95E+00 | 4.55E−02 |
| 5.97E+00 | 2.11E+04 | 5.99E+00 | 1.91E+01 | 5.99E+00 | 3.93E−02 |
| 6.00E+00 | 2.06E+04 | 6.02E+00 | 1.14E+01 | 6.02E+00 | 3.31E−02 |
| 6.03E+00 | 2.06E+04 | 6.05E+00 | 4.01E+01 | 6.05E+00 | 2.48E−02 |
| 6.06E+00 | 2.08E+04 | 6.09E+00 | 2.29E+01 | 6.08E+00 | 3.52E−02 |
| 6.09E+00 | 2.08E+04 | 6.12E+00 | 2.29E+01 | 6.11E+00 | 3.11E−02 |
| 6.13E+00 | 2.07E+04 | 6.15E+00 | 3.05E+01 | 6.14E+00 | 3.31E−02 |
| 6.16E+00 | 2.07E+04 | 6.18E+00 | 1.91E+01 | 6.17E+00 | 3.93E−02 |
| 6.19E+00 | 2.06E+04 | 6.21E+00 | 3.43E+01 | 6.20E+00 | 3.52E−02 |
| 6.22E+00 | 2.11E+04 | 6.24E+00 | 2.67E+01 | 6.23E+00 | 4.14E−02 |
| 6.25E+00 | 2.06E+04 | 6.27E+00 | 2.48E+01 | 6.26E+00 | 3.11E−02 |
| 6.28E+00 | 2.12E+04 | 6.30E+00 | 2.10E+01 | 6.29E+00 | 3.93E−02 |
| 6.31E+00 | 2.11E+04 | 6.33E+00 | 2.10E+01 | 6.32E+00 | 2.69E−02 |
| 6.34E+00 | 2.10E+04 | 6.36E+00 | 1.34E+01 | 6.35E+00 | 1.04E−02 |
| 6.37E+00 | 2.12E+04 | 6.39E+00 | 1.53E+01 | 6.38E+00 | 4.97E−02 |
| 6.40E+00 | 2.12E+04 | 6.42E+00 | 2.29E+01 | 6.41E+00 | 3.11E−02 |
| 6.43E+00 | 2.14E+04 | 6.45E+00 | 1.72E+01 | 6.44E+00 | 3.93E−02 |
| 6.46E+00 | 2.10E+04 | 6.48E+00 | 1.72E+01 | 6.47E+00 | 3.93E−02 |
| 6.49E+00 | 2.13E+04 | 6.51E+00 | 2.48E+01 | 6.50E+00 | 2.28E−02 |
| 6.52E+00 | 2.11E+04 | 6.54E+00 | 2.86E+01 | 6.54E+00 | 3.73E−02 |
| 6.55E+00 | 2.15E+04 | 6.58E+00 | 1.53E+01 | 6.57E+00 | 1.45E−02 |
| 6.58E+00 | 2.11E+04 | 6.61E+00 | 1.14E+01 | 6.60E+00 | 2.48E−02 |
| 6.61E+00 | 2.12E+04 | 6.64E+00 | 1.53E+01 | 6.63E+00 | 3.11E−02 |
| 6.64E+00 | 2.12E+04 | 6.67E+00 | 9.54E+00 | 6.66E+00 | 2.90E−02 |
| 6.68E+00 | 2.12E+04 | 6.70E+00 | 1.34E+01 | 6.69E+00 | 1.86E−02 |
| 6.71E+00 | 2.17E+04 | 6.73E+00 | 1.14E+01 | 6.72E+00 | 2.28E−02 |
| 6.74E+00 | 2.13E+04 | 6.76E+00 | 1.34E+01 | 6.75E+00 | 3.93E−02 |
| 6.77E+00 | 2.13E+04 | 6.79E+00 | 1.53E+01 | 6.78E+00 | 1.24E−02 |
| 6.80E+00 | 2.16E+04 | 6.82E+00 | 3.24E+01 | 6.81E+00 | 2.90E−02 |
| 6.83E+00 | 2.11E+04 | 6.85E+00 | 1.72E+01 | 6.84E+00 | 2.90E−02 |
| 6.86E+00 | 2.17E+04 | 6.88E+00 | 1.53E+01 | 6.87E+00 | 3.11E−02 |
| 6.89E+00 | 2.12E+04 | 6.91E+00 | 1.14E+01 | 6.90E+00 | 2.69E−02 |
| 6.92E+00 | 2.11E+04 | 6.94E+00 | 1.53E+01 | 6.93E+00 | 3.73E−02 |
| 6.95E+00 | 2.19E+04 | 6.97E+00 | 1.53E+01 | 6.96E+00 | 4.76E−02 |
| 6.98E+00 | 2.16E+04 | 7.00E+00 | 1.53E+01 | 6.99E+00 | 2.69E−02 |
| 7.01E+00 | 2.16E+04 | 7.03E+00 | 9.54E+00 | 7.02E+00 | 3.52E−02 |
| 7.04E+00 | 2.17E+04 | 7.06E+00 | 1.34E+01 | 7.06E+00 | 2.69E−02 |
| 7.07E+00 | 2.18E+04 | 7.09E+00 | 9.54E+00 | 7.09E+00 | 2.69E−02 |
| 7.10E+00 | 2.18E+04 | 7.13E+00 | 9.54E+00 | 7.12E+00 | 1.66E−02 |
| 7.13E+00 | 2.17E+04 | 7.16E+00 | 1.53E+01 | 7.15E+00 | 1.66E−02 |
| 7.16E+00 | 2.15E+04 | 7.19E+00 | 2.86E+01 | 7.18E+00 | 3.31E−02 |
| 7.19E+00 | 2.14E+04 | 7.22E+00 | 1.72E+01 | 7.21E+00 | 2.07E−02 |
| 7.23E+00 | 2.19E+04 | 7.25E+00 | 1.34E+01 | 7.24E+00 | 3.52E−02 |
| 7.26E+00 | 2.17E+04 | 7.28E+00 | 1.14E+01 | 7.27E+00 | 2.90E−02 |
| 7.29E+00 | 2.14E+04 | 7.31E+00 | 2.10E+01 | 7.30E+00 | 3.31E−02 |
| 7.32E+00 | 2.17E+04 | 7.34E+00 | 5.72E+00 | 7.33E+00 | 2.28E−02 |
| 7.35E+00 | 2.18E+04 | 7.37E+00 | 2.48E+01 | 7.36E+00 | 2.69E−02 |
| 7.38E+00 | 2.18E+04 | 7.40E+00 | 5.72E+00 | 7.39E+00 | 2.28E−02 |
| 7.41E+00 | 2.18E+04 | 7.43E+00 | 1.34E+01 | 7.42E+00 | 3.11E−02 |
| 7.44E+00 | 2.15E+04 | 7.46E+00 | 1.14E+01 | 7.45E+00 | 2.28E−02 |
| 7.47E+00 | 2.22E+04 | 7.49E+00 | 2.29E+01 | 7.48E+00 | 2.48E−02 |
| 7.50E+00 | 2.19E+04 | 7.52E+00 | 1.53E+01 | 7.51E+00 | 1.45E−02 |
| 7.53E+00 | 2.18E+04 | 7.55E+00 | 9.54E+00 | 7.54E+00 | 1.66E−02 |
| 7.56E+00 | 2.21E+04 | 7.58E+00 | 1.14E+01 | 7.58E+00 | 1.45E−02 |
| 7.59E+00 | 2.19E+04 | 7.61E+00 | 7.63E+00 | 7.61E+00 | 1.45E−02 |
| 7.62E+00 | 2.20E+04 | 7.65E+00 | 2.10E+01 | 7.64E+00 | 1.86E−02 |
| 7.65E+00 | 2.23E+04 | 7.68E+00 | 1.91E+00 | 7.67E+00 | 1.66E−02 |
| 7.68E+00 | 2.18E+04 | 7.71E+00 | 1.91E+01 | 7.70E+00 | 1.86E−02 |
| 7.72E+00 | 2.22E+04 | 7.74E+00 | 7.63E+00 | 7.73E+00 | 8.28E−03 |
| 7.75E+00 | 2.23E+04 | 7.77E+00 | 9.54E+00 | 7.76E+00 | 1.66E−02 |
| 7.78E+00 | 2.22E+04 | 7.80E+00 | 1.14E+01 | 7.79E+00 | 1.66E−02 |
| 7.81E+00 | 2.23E+04 | 7.83E+00 | 5.72E+00 | 7.82E+00 | 1.86E−02 |
| 7.84E+00 | 2.24E+04 | 7.86E+00 | 1.53E+01 | 7.85E+00 | 1.86E−02 |
| 7.87E+00 | 2.23E+04 | 7.89E+00 | 1.34E+01 | 7.88E+00 | 1.24E−02 |
| 7.90E+00 | 2.21E+04 | 7.92E+00 | 5.72E+00 | 7.91E+00 | 2.48E−02 |
| 7.93E+00 | 2.26E+04 | 7.95E+00 | 5.72E+00 | 7.94E+00 | 1.45E−02 |
| 7.96E+00 | 2.27E+04 | 7.98E+00 | 9.54E+00 | 7.97E+00 | 2.48E−02 |
| 7.99E+00 | 2.26E+04 | 8.01E+00 | 1.34E+01 | 8.00E+00 | 2.48E−02 |
| 8.02E+00 | 2.23E+04 | 8.04E+00 | 1.53E+01 | 8.03E+00 | 2.48E−02 |
| 8.05E+00 | 2.18E+04 | 8.07E+00 | 9.54E+00 | 8.06E+00 | 1.24E−02 |
| 8.08E+00 | 2.22E+04 | 8.10E+00 | 5.72E+00 | 8.10E+00 | 8.28E−03 |
| 8.11E+00 | 2.23E+04 | 8.13E+00 | 9.54E+00 | 8.13E+00 | 2.48E−02 |
| 8.14E+00 | 2.28E+04 | 8.16E+00 | 1.14E+01 | 8.16E+00 | 2.28E−02 |
| 8.17E+00 | 2.27E+04 | 8.20E+00 | 3.81E+00 | 8.19E+00 | 1.04E−02 |
| 8.20E+00 | 2.26E+04 | 8.23E+00 | 5.72E+00 | 8.22E+00 | 1.86E−02 |
| 8.24E+00 | 2.27E+04 | 8.26E+00 | 9.54E+00 | 8.25E+00 | 1.45E−02 |
| 8.27E+00 | 2.26E+04 | 8.29E+00 | 1.14E+01 | 8.28E+00 | 2.07E−02 |
| 8.30E+00 | 2.27E+04 | 8.32E+00 | 9.54E+00 | 8.31E+00 | 2.69E−02 |
| 8.33E+00 | 2.22E+04 | 8.35E+00 | 1.14E+01 | 8.34E+00 | 1.24E−02 |
| 8.36E+00 | 2.29E+04 | 8.38E+00 | 3.81E+00 | 8.37E+00 | 1.86E−02 |
| 8.39E+00 | 2.25E+04 | 8.41E+00 | 3.81E+00 | 8.40E+00 | 1.45E−02 |
| 8.42E+00 | 2.23E+04 | 8.44E+00 | 7.63E+00 | 8.43E+00 | 1.86E−02 |
| 8.45E+00 | 2.27E+04 | 8.47E+00 | 5.72E+00 | 8.46E+00 | 1.45E−02 |
| 8.48E+00 | 2.26E+04 | 8.50E+00 | 3.81E+00 | 8.49E+00 | 6.21E−03 |
| 8.51E+00 | 2.25E+04 | 8.53E+00 | 3.81E+00 | 8.52E+00 | 2.07E−02 |
| 8.54E+00 | 2.24E+04 | 8.56E+00 | 9.54E+00 | 8.55E+00 | 1.24E−02 |
| 8.57E+00 | 2.25E+04 | 8.59E+00 | 1.14E+01 | 8.58E+00 | 1.24E−02 |
| 8.60E+00 | 2.27E+04 | 8.62E+00 | 3.81E+00 | 8.61E+00 | 1.04E−02 |
| 8.63E+00 | 2.25E+04 | 8.65E+00 | 3.81E+00 | 8.65E+00 | 8.28E−03 |
| 8.66E+00 | 2.27E+04 | 8.68E+00 | 7.63E+00 | 8.68E+00 | 1.45E−02 |
| 8.69E+00 | 2.26E+04 | 8.72E+00 | 5.72E+00 | 8.71E+00 | 1.86E−02 |
| 8.72E+00 | 2.31E+04 | 8.75E+00 | 3.81E+00 | 8.74E+00 | 1.66E−02 |
| 8.75E+00 | 2.30E+04 | 8.78E+00 | 1.91E+00 | 8.77E+00 | 1.66E−02 |
| 8.79E+00 | 2.26E+04 | 8.81E+00 | 7.63E+00 | 8.80E+00 | 8.28E−03 |
| 8.82E+00 | 2.30E+04 | 8.84E+00 | 1.91E+00 | 8.83E+00 | 2.90E−02 |
| 8.85E+00 | 2.29E+04 | 8.87E+00 | 7.63E+00 | 8.86E+00 | 1.04E−02 |
| 8.88E+00 | 2.29E+04 | 8.90E+00 | 7.63E+00 | 8.89E+00 | 1.04E−02 |
| 8.91E+00 | 2.28E+04 | 8.93E+00 | 5.72E−01 | 8.92E+00 | 1.86E−02 |
| 8.94E+00 | 2.30E+04 | 8.96E+00 | 5.72E+00 | 8.95E+00 | 1.04E−02 |
| 8.97E+00 | 2.33E+04 | 8.99E+00 | 3.81E+00 | 8.98E+00 | 8.28E−03 |
| 9.00E+00 | 2.28E+04 | 9.02E+00 | 3.81E+00 | 9.01E+00 | 2.69E−02 |
| 9.03E+00 | 2.31E+04 | 9.05E+00 | 9.54E+00 | 9.04E+00 | 2.28E−02 |
| 9.06E+00 | 2.32E+04 | 9.08E+00 | 7.63E+00 | 9.07E+00 | 1.86E−02 |
| 9.09E+00 | 2.29E+04 | 9.11E+00 | 3.81E+00 | 9.10E+00 | 1.45E−02 |
| 9.12E+00 | 2.32E+04 | 9.14E+00 | 3.81E+00 | 9.13E+00 | 8.28E−03 |
| 9.15E+00 | 2.25E+04 | 9.17E+00 | 9.54E+00 | 9.16E+00 | 1.66E−02 |
| 9.18E+00 | 2.31E+04 | 9.21E+00 | 5.72E−01 | 9.20E+00 | 6.21E−03 |
| 9.21E+00 | 2.30E+04 | 9.24E+00 | 5.72E−01 | 9.23E+00 | 2.28E−02 |
| 9.24E+00 | 2.27E+04 | 9.27E+00 | 3.81E+00 | 9.26E+00 | 1.86E−02 |
| 9.27E+00 | 2.34E+04 | 9.30E+00 | 7.63E+00 | 9.29E+00 | 2.28E−02 |
| 9.30E+00 | 2.33E+04 | 9.33E+00 | 1.91E+00 | 9.32E+00 | 2.07E−02 |
| 9.34E+00 | 2.34E+04 | 9.36E+00 | 9.54E+00 | 9.35E+00 | 1.45E−02 |
| 9.37E+00 | 2.35E+04 | 9.39E+00 | 5.72E+00 | 9.38E+00 | 1.45E−02 |
| 9.40E+00 | 2.31E+04 | 9.42E+00 | 3.81E+00 | 9.41E+00 | 2.07E−03 |
| 9.43E+00 | 2.33E+04 | 9.45E+00 | 5.72E−01 | 9.44E+00 | 1.24E−02 |
| 9.46E+00 | 2.33E+04 | 9.48E+00 | 3.81E+00 | 9.47E+00 | 8.28E−03 |
| 9.49E+00 | 2.29E+04 | 9.51E+00 | 5.72E+00 | 9.50E+00 | 8.28E−03 |
| 9.52E+00 | 2.30E+04 | 9.54E+00 | 5.72E+00 | 9.53E+00 | 1.04E−02 |
| 9.55E+00 | 2.34E+04 | 9.57E+00 | 5.72E+00 | 9.56E+00 | 1.66E−02 |
| 9.58E+00 | 2.30E+04 | 9.60E+00 | 1.91E+00 | 9.59E+00 | 1.45E−02 |
| 9.61E+00 | 2.31E+04 | 9.63E+00 | 1.91E+00 | 9.62E+00 | 6.21E−03 |
| 9.64E+00 | 2.32E+04 | 9.66E+00 | 3.81E+00 | 9.65E+00 | 2.07E−02 |
| 9.67E+00 | 2.32E+04 | 9.69E+00 | 1.91E+00 | 9.69E+00 | 4.14E−03 |
| 9.70E+00 | 2.30E+04 | 9.72E+00 | 3.81E+00 | 9.72E+00 | 2.07E−02 |
| 9.73E+00 | 2.31E+04 | 9.76E+00 | 5.72E+00 | 9.75E+00 | 1.66E−02 |
| 9.76E+00 | 2.37E+04 | 9.79E+00 | 3.81E+00 | 9.78E+00 | 8.28E−03 |
| 9.79E+00 | 2.35E+04 | 9.82E+00 | 5.72E+00 | 9.81E+00 | 6.21E−03 |
| 9.83E+00 | 2.33E+04 | 9.85E+00 | 3.81E+00 | 9.84E+00 | 8.28E−03 |
| 9.86E+00 | 2.30E+04 | 9.88E+00 | 1.91E+00 | 9.87E+00 | 1.04E−02 |
| 9.89E+00 | 2.34E+04 | 9.91E+00 | 7.63E+00 | 9.90E+00 | 1.04E−02 |
| 9.92E+00 | 2.35E+04 | 9.94E+00 | 3.81E+00 | 9.93E+00 | 8.28E−03 |
| 9.95E+00 | 2.32E+04 | 9.97E+00 | 1.14E+01 | 9.96E+00 | 8.28E−03 |
| 9.98E+00 | 2.31E+04 | 1.00E+01 | 3.81E+00 | 9.99E+00 | 1.24E−02 |
| 1.00E+01 | 2.37E+04 | 1.00E+01 | 1.91E+00 | 1.00E+01 | 4.14E−03 |
| 1.00E+01 | 2.38E+04 | 1.01E+01 | 1.91E+00 | 1.01E+01 | 8.28E−03 |
| 1.01E+01 | 2.38E+04 | 1.01E+01 | 5.72E+00 | 1.01E+01 | 1.66E−02 |
| 1.01E+01 | 2.38E+04 | 1.01E+01 | 3.81E+00 | 1.01E+01 | 1.04E−02 |
| 1.01E+01 | 2.36E+04 | 1.02E+01 | 5.72E−01 | 1.01E+01 | 1.24E−02 |
| 1.02E+01 | 2.38E+04 | 1.02E+01 | 5.72E−01 | 1.02E+01 | 0.00E+00 |
| 1.02E+01 | 2.36E+04 | 1.02E+01 | 1.91E+00 | 1.02E+01 | 1.45E−02 |
| 1.02E+01 | 2.33E+04 | 1.02E+01 | 9.54E+00 | 1.02E+01 | 8.28E−03 |
| 1.03E+01 | 2.36E+04 | 1.03E+01 | 3.81E+00 | 1.03E+01 | 1.04E−02 |
| 1.03E+01 | 2.30E+04 | 1.03E+01 | 1.91E+00 | 1.03E+01 | 1.24E−02 |
| 1.03E+01 | 2.34E+04 | 1.03E+01 | 1.91E+00 | 1.03E+01 | 6.21E−03 |
| 1.03E+01 | 2.36E+04 | 1.04E+01 | 3.81E+00 | 1.04E+01 | 0.00E+00 |
| 1.04E+01 | 2.34E+04 | 1.04E+01 | 1.91E+00 | 1.04E+01 | 2.07E−03 |
| 1.04E+01 | 2.36E+04 | 1.04E+01 | 5.72E+00 | 1.04E+01 | 0.00E+00 |
| 1.04E+01 | 2.36E+04 | 1.05E+01 | 1.91E+00 | 1.04E+01 | 6.21E−03 |
| 1.05E+01 | 2.41E+04 | 1.05E+01 | 3.81E+00 | 1.05E+01 | 6.21E−03 |
| 1.05E+01 | 2.37E+04 | 1.05E+01 | 5.72E−01 | 1.05E+01 | 8.28E−03 |
| 1.05E+01 | 2.38E+04 | 1.06E+01 | 3.81E+00 | 1.05E+01 | 1.04E−02 |
| 1.06E+01 | 2.37E+04 | 1.06E+01 | 1.91E+00 | 1.06E+01 | 6.21E−03 |
| 1.06E+01 | 2.40E+04 | 1.06E+01 | 5.72E−01 | 1.06E+01 | 2.07E−03 |
| 1.06E+01 | 2.41E+04 | 1.06E+01 | 5.72E+00 | 1.06E+01 | 1.24E−02 |
| 1.07E+01 | 2.37E+04 | 1.07E+01 | 5.72E−01 | 1.07E+01 | 6.21E−03 |
| 1.07E+01 | 2.38E+04 | 1.07E+01 | 3.81E+00 | 1.07E+01 | 1.86E−02 |
| 1.07E+01 | 2.43E+04 | 1.07E+01 | 1.91E+00 | 1.07E+01 | 4.14E−03 |
| 1.07E+01 | 2.40E+04 | 1.08E+01 | 1.91E+00 | 1.08E+01 | 1.24E−02 |
| 1.08E+01 | 2.40E+04 | 1.08E+01 | 1.91E+00 | 1.08E+01 | 2.07E−03 |
| 1.08E+01 | 2.38E+04 | 1.08E+01 | 5.72E−01 | 1.08E+01 | 1.45E−02 |
| 1.08E+01 | 2.40E+04 | 1.09E+01 | 1.91E+00 | 1.08E+01 | 6.21E−03 |
| 1.09E+01 | 2.42E+04 | 1.09E+01 | 1.91E+00 | 1.09E+01 | 8.28E−03 |
| 1.09E+01 | 2.41E+04 | 1.09E+01 | 1.91E+00 | 1.09E+01 | 6.21E−03 |
| 1.09E+01 | 2.41E+04 | 1.09E+01 | 5.72E+00 | 1.09E+01 | 1.04E−02 |
| 1.10E+01 | 2.35E+04 | 1.10E+01 | 1.91E+00 | 1.10E+01 | 1.04E−02 |
| 1.10E+01 | 2.39E+04 | 1.10E+01 | 5.72E−01 | 1.10E+01 | 1.04E−02 |
| 1.10E+01 | 2.36E+04 | 1.10E+01 | 1.91E+00 | 1.10E+01 | 6.21E−03 |
| 1.10E+01 | 2.34E+04 | 1.11E+01 | 5.72E−01 | 1.11E+01 | 1.04E−02 |
| 1.11E+01 | 2.41E+04 | 1.11E+01 | 3.81E+00 | 1.11E+01 | 8.28E−03 |
| 1.11E+01 | 2.36E+04 | 1.11E+01 | 1.91E+00 | 1.11E+01 | 4.14E−03 |
| 1.11E+01 | 2.35E+04 | 1.12E+01 | 1.91E+00 | 1.12E+01 | 0.00E+00 |
| 1.12E+01 | 2.41E+04 | 1.12E+01 | 1.91E+00 | 1.12E+01 | 6.21E−03 |
| 1.12E+01 | 2.38E+04 | 1.12E+01 | 1.91E+00 | 1.12E+01 | 2.07E−03 |
| 1.12E+01 | 2.36E+04 | 1.13E+01 | 5.72E+00 | 1.12E+01 | 6.21E−03 |
| 1.13E+01 | 2.41E+04 | 1.13E+01 | 1.91E+00 | 1.13E+01 | 4.14E−03 |
| 1.13E+01 | 2.40E+04 | 1.13E+01 | 5.72E−01 | 1.13E+01 | 1.66E−02 |
| 1.13E+01 | 2.42E+04 | 1.13E+01 | 9.54E+00 | 1.13E+01 | 2.07E−03 |
| 1.14E+01 | 2.38E+04 | 1.14E+01 | 1.91E+00 | 1.14E+01 | 4.14E−03 |
| 1.14E+01 | 2.39E+04 | 1.14E+01 | 3.81E+00 | 1.14E+01 | 2.07E−03 |
| 1.14E+01 | 2.43E+04 | 1.14E+01 | 3.81E+00 | 1.14E+01 | 1.45E−02 |
| 1.14E+01 | 2.41E+04 | 1.15E+01 | 5.72E−01 | 1.15E+01 | 2.07E−03 |
| 1.15E+01 | 2.41E+04 | 1.15E+01 | 5.72E+00 | 1.15E+01 | 6.21E−03 |
| 1.15E+01 | 2.43E+04 | 1.15E+01 | 5.72E+00 | 1.15E+01 | 6.21E−03 |
| 1.15E+01 | 2.40E+04 | 1.16E+01 | 5.72E+00 | 1.16E+01 | 1.04E−02 |
| 1.16E+01 | 2.36E+04 | 1.16E+01 | 5.72E+00 | 1.16E+01 | 4.14E−03 |
| 1.16E+01 | 2.41E+04 | 1.16E+01 | 5.72E−01 | 1.16E+01 | 2.07E−03 |
| 1.16E+01 | 2.38E+04 | 1.17E+01 | 5.72E−01 | 1.16E+01 | 1.04E−02 |
| 1.17E+01 | 2.38E+04 | 1.17E+01 | 3.81E+00 | 1.17E+01 | 6.21E−03 |
| 1.17E+01 | 2.39E+04 | 1.17E+01 | 5.72E−01 | 1.17E+01 | 4.14E−03 |
| 1.17E+01 | 2.43E+04 | 1.17E+01 | 1.91E+00 | 1.17E+01 | 6.21E−03 |
| 1.18E+01 | 2.40E+04 | 1.18E+01 | 1.91E+00 | 1.18E+01 | 6.21E−03 |
| 1.18E+01 | 2.41E+04 | 1.18E+01 | 5.72E+00 | 1.18E+01 | 6.21E−03 |
| 1.18E+01 | 2.39E+04 | 1.18E+01 | 3.81E+00 | 1.18E+01 | 8.28E−03 |
| 1.18E+01 | 2.41E+04 | 1.19E+01 | 1.91E+00 | 1.19E+01 | 4.14E−03 |
| 1.19E+01 | 2.41E+04 | 1.19E+01 | 1.91E+00 | 1.19E+01 | 6.21E−03 |
| 1.19E+01 | 2.40E+04 | 1.19E+01 | 3.81E+00 | 1.19E+01 | 4.14E−03 |
| 1.19E+01 | 2.43E+04 | 1.20E+01 | 5.72E+00 | 1.19E+01 | 6.21E−03 |
| 1.20E+01 | 2.40E+04 | 1.20E+01 | 5.72E−01 | 1.20E+01 | 4.14E−03 |
| 1.20E+01 | 2.42E+04 | 1.20E+01 | 3.81E+00 | 1.20E+01 | 2.07E−03 |
| 1.20E+01 | 2.41E+04 | 1.20E+01 | 5.72E−01 | 1.20E+01 | 6.21E−03 |
| 1.21E+01 | 2.40E+04 | 1.21E+01 | 5.72E−01 | 1.21E+01 | 0.00E+00 |
| 1.21E+01 | 2.41E+04 | 1.21E+01 | 3.81E+00 | 1.21E+01 | 0.00E+00 |
| 1.21E+01 | 2.44E+04 | 1.21E+01 | 5.72E−01 | 1.21E+01 | 1.86E−02 |
| 1.21E+01 | 2.39E+04 | 1.22E+01 | 5.72E−01 | 1.22E+01 | 2.07E−03 |
| 1.22E+01 | 2.41E+04 | 1.22E+01 | 1.91E+00 | 1.22E+01 | 2.07E−03 |
| 1.22E+01 | 2.40E+04 | 1.22E+01 | 1.91E+00 | 1.22E+01 | 1.04E−02 |
| 1.22E+01 | 2.40E+04 | 1.23E+01 | 5.72E−01 | 1.23E+01 | 4.14E−03 |
| 1.23E+01 | 2.42E+04 | 1.23E+01 | 1.91E+00 | 1.23E+01 | 8.28E−03 |
| 1.23E+01 | 2.39E+04 | 1.23E+01 | 5.72E+00 | 1.23E+01 | 6.21E−03 |
| 1.23E+01 | 2.42E+04 | 1.24E+01 | 3.81E+00 | 1.23E+01 | 0.00E+00 |
| 1.24E+01 | 2.44E+04 | 1.24E+01 | 3.81E+00 | 1.24E+01 | 8.28E−03 |
| 1.24E+01 | 2.43E+04 | 1.24E+01 | 3.81E+00 | 1.24E+01 | 6.21E−03 |
| 1.24E+01 | 2.48E+04 | 1.24E+01 | 5.72E−01 | 1.24E+01 | 6.21E−03 |
| 1.25E+01 | 2.41E+04 | 1.25E+01 | 5.72E−01 | 1.25E+01 | 4.14E−03 |
| 1.25E+01 | 2.42E+04 | 1.25E+01 | 5.72E−01 | 1.25E+01 | 2.07E−03 |
| 1.25E+01 | 2.41E+04 | 1.25E+01 | 5.72E−01 | 1.25E+01 | 1.45E−02 |
| 1.25E+01 | 2.43E+04 | 1.26E+01 | 1.91E+00 | 1.26E+01 | 8.28E−03 |
| 1.26E+01 | 2.43E+04 | 1.26E+01 | 5.72E−01 | 1.26E+01 | 0.00E+00 |
| 1.26E+01 | 2.43E+04 | 1.26E+01 | 5.72E+00 | 1.26E+01 | 6.21E−03 |
| 1.26E+01 | 2.43E+04 | 1.27E+01 | 3.81E+00 | 1.27E+01 | 8.28E−03 |
| 1.27E+01 | 2.41E+04 | 1.27E+01 | 3.81E+00 | 1.27E+01 | 4.14E−03 |
| 1.27E+01 | 2.46E+04 | 1.27E+01 | 3.81E+00 | 1.27E+01 | 2.07E−03 |
| 1.27E+01 | 2.43E+04 | 1.28E+01 | 5.72E+00 | 1.27E+01 | 0.00E+00 |
| 1.28E+01 | 2.42E+04 | 1.28E+01 | 3.81E+00 | 1.28E+01 | 0.00E+00 |
| 1.28E+01 | 2.46E+04 | 1.28E+01 | 1.91E+00 | 1.28E+01 | 0.00E+00 |
| 1.28E+01 | 2.43E+04 | 1.28E+01 | 1.91E+00 | 1.28E+01 | 6.21E−03 |
| 1.29E+01 | 2.45E+04 | 1.29E+01 | 5.72E−01 | 1.29E+01 | 8.28E−03 |
| 1.29E+01 | 2.42E+04 | 1.29E+01 | 3.81E+00 | 1.29E+01 | 4.14E−03 |
| 1.29E+01 | 2.39E+04 | 1.29E+01 | 5.72E−01 | 1.29E+01 | 6.21E−03 |
| 1.29E+01 | 2.41E+04 | 1.30E+01 | 5.72E−01 | 1.30E+01 | 1.66E−02 |
| 1.30E+01 | 2.41E+04 | 1.30E+01 | 3.81E+00 | 1.30E+01 | 1.04E−02 |
| 1.30E+01 | 2.45E+04 | 1.30E+01 | 5.72E−01 | 1.30E+01 | 4.14E−03 |
| 1.30E+01 | 2.44E+04 | 1.31E+01 | 1.91E+00 | 1.30E+01 | 0.00E+00 |
| 1.31E+01 | 2.38E+04 | 1.31E+01 | 3.81E+00 | 1.31E+01 | 4.14E−03 |
| 1.31E+01 | 2.44E+04 | 1.31E+01 | 5.72E−01 | 1.31E+01 | 2.07E−03 |
| 1.31E+01 | 2.41E+04 | 1.31E+01 | 1.91E+00 | 1.31E+01 | 2.07E−03 |
| 1.32E+01 | 2.41E+04 | 1.32E+01 | 1.91E+00 | 1.32E+01 | 4.14E−03 |
| 1.32E+01 | 2.41E+04 | 1.32E+01 | 1.91E+00 | 1.32E+01 | 6.21E−03 |
| 1.32E+01 | 2.43E+04 | 1.32E+01 | 3.81E+00 | 1.32E+01 | 4.14E−03 |
| 1.32E+01 | 2.45E+04 | 1.33E+01 | 5.72E−01 | 1.33E+01 | 2.07E−03 |
| 1.33E+01 | 2.44E+04 | 1.33E+01 | 3.81E+00 | 1.33E+01 | 6.21E−03 |
| 1.33E+01 | 2.42E+04 | 1.33E+01 | 1.91E+00 | 1.33E+01 | 4.14E−03 |
| 1.33E+01 | 2.43E+04 | 1.34E+01 | 1.91E+00 | 1.34E+01 | 2.07E−03 |
| 1.34E+01 | 2.41E+04 | 1.34E+01 | 1.91E+00 | 1.34E+01 | 0.00E+00 |
| 1.34E+01 | 2.45E+04 | 1.34E+01 | 5.72E+00 | 1.34E+01 | 4.14E−03 |
| 1.34E+01 | 2.44E+04 | 1.35E+01 | 1.91E+00 | 1.34E+01 | 2.07E−03 |
| 1.35E+01 | 2.46E+04 | 1.35E+01 | 1.91E+00 | 1.35E+01 | 2.07E−03 |
| 1.35E+01 | 2.44E+04 | 1.35E+01 | 5.72E−01 | 1.35E+01 | 0.00E+00 |
| 1.35E+01 | 2.39E+04 | 1.35E+01 | 5.72E+00 | 1.35E+01 | 2.07E−03 |
| 1.36E+01 | 2.39E+04 | 1.36E+01 | 1.91E+00 | 1.36E+01 | 0.00E+00 |
| 1.36E+01 | 2.40E+04 | 1.36E+01 | 1.91E+00 | 1.36E+01 | 0.00E+00 |
| 1.36E+01 | 2.40E+04 | 1.36E+01 | 1.91E+00 | 1.36E+01 | 2.07E−03 |
| 1.36E+01 | 2.44E+04 | 1.37E+01 | 1.91E+00 | 1.37E+01 | 4.14E−03 |
| 1.37E+01 | 2.46E+04 | 1.37E+01 | 5.72E−01 | 1.37E+01 | 0.00E+00 |
| 1.37E+01 | 2.44E+04 | 1.37E+01 | 1.91E+00 | 1.37E+01 | 4.14E−03 |
| 1.37E+01 | 2.41E+04 | 1.38E+01 | 1.91E+00 | 1.38E+01 | 4.14E−03 |
| 1.38E+01 | 2.42E+04 | 1.38E+01 | 1.91E+00 | 1.38E+01 | 8.28E−03 |
| 1.38E+01 | 2.40E+04 | 1.38E+01 | 5.72E−01 | 1.38E+01 | 0.00E+00 |
| 1.38E+01 | 2.46E+04 | 1.39E+01 | 5.72E−01 | 1.38E+01 | 2.07E−03 |
| 1.39E+01 | 2.47E+04 | 1.39E+01 | 1.91E+00 | 1.39E+01 | 4.14E−03 |
| 1.39E+01 | 2.41E+04 | 1.39E+01 | 1.91E+00 | 1.39E+01 | 6.21E−03 |
| 1.39E+01 | 2.40E+04 | 1.39E+01 | 5.72E−01 | 1.39E+01 | 4.14E−03 |
| 1.40E+01 | 2.44E+04 | 1.40E+01 | 1.91E+00 | 1.40E+01 | 8.28E−03 |
| 1.40E+01 | 2.42E+04 | 1.40E+01 | 5.72E+00 | 1.40E+01 | 2.07E−03 |
| 1.40E+01 | 2.44E+04 | 1.40E+01 | 1.91E+00 | 1.40E+01 | 2.07E−03 |
| 1.40E+01 | 2.41E+04 | 1.41E+01 | 1.91E+00 | 1.41E+01 | 6.21E−03 |
| 1.41E+01 | 2.44E+04 | 1.41E+01 | 1.91E+00 | 1.41E+01 | 8.28E−03 |
| 1.41E+01 | 2.41E+04 | 1.41E+01 | 1.91E+00 | 1.41E+01 | 2.07E−03 |
| 1.41E+01 | 2.36E+04 | 1.42E+01 | 3.81E+00 | 1.41E+01 | 2.07E−03 |
| 1.42E+01 | 2.43E+04 | 1.42E+01 | 3.81E+00 | 1.42E+01 | 4.14E−03 |
| 1.42E+01 | 2.42E+04 | 1.42E+01 | 5.72E−01 | 1.42E+01 | 0.00E+00 |
| 1.42E+01 | 2.45E+04 | 1.43E+01 | 5.72E−01 | 1.42E+01 | 0.00E+00 |
| 1.43E+01 | 2.44E+04 | 1.43E+01 | 3.81E+00 | 1.43E+01 | 4.14E−03 |
| 1.43E+01 | 2.51E+04 | 1.43E+01 | 1.91E+00 | 1.43E+01 | 4.14E−03 |
| 1.43E+01 | 2.43E+04 | 1.43E+01 | 1.91E+00 | 1.43E+01 | 4.14E−03 |
| 1.44E+01 | 2.44E+04 | 1.44E+01 | 5.72E−01 | 1.44E+01 | 4.14E−03 |
| 1.44E+01 | 2.45E+04 | 1.44E+01 | 3.81E+00 | 1.44E+01 | 4.14E−03 |
| 1.44E+01 | 2.41E+04 | 1.44E+01 | 1.91E+00 | 1.44E+01 | 0.00E+00 |
| 1.44E+01 | 2.44E+04 | 1.45E+01 | 3.81E+00 | 1.45E+01 | 4.14E−03 |
| 1.45E+01 | 2.45E+04 | 1.45E+01 | 3.81E+00 | 1.45E+01 | 6.21E−03 |
| 1.45E+01 | 2.46E+04 | 1.45E+01 | 5.72E−01 | 1.45E+01 | 1.04E−02 |
| 1.45E+01 | 2.45E+04 | 1.46E+01 | 1.91E+00 | 1.45E+01 | 2.07E−03 |

TABLE 2

| Depth | | Depth | | Depth | |
|---|---|---|---|---|---|
| (nm) | Silicon | (nm) | Oxygen | (nm) | Nitrogen |
| 8.91E−03 | 9.00E+03 | 3.12E−02 | 2.65E+04 | 2.23E−02 | 1.05E+22 |
| 3.92E−02 | 4.92E+03 | 6.15E−02 | 2.91E+04 | 5.26E−02 | 2.92E+21 |
| 7.04E−02 | 4.74E+03 | 9.18E−02 | 3.22E+04 | 8.29E−02 | 1.33E+21 |
| 1.01E−01 | 4.87E+03 | 1.23E−01 | 3.41E+04 | 1.14E−01 | 9.04E+20 |
| 1.31E−01 | 5.24E+03 | 1.53E−01 | 3.54E+04 | 1.44E−01 | 8.77E+20 |
| 1.62E−01 | 5.48E+03 | 1.84E−01 | 3.58E+04 | 1.75E−01 | 1.05E+21 |
| 1.93E−01 | 5.46E+03 | 2.14E−01 | 3.63E+04 | 2.06E−01 | 1.11E+21 |
| 2.23E−01 | 5.81E+03 | 2.45E−01 | 3.60E+04 | 2.36E−01 | 1.28E+21 |
| 2.54E−01 | 6.04E+03 | 2.75E−01 | 3.68E+04 | 2.67E−01 | 1.38E+21 |
| 2.84E−01 | 6.06E+03 | 3.06E−01 | 3.64E+04 | 2.98E−01 | 1.62E+21 |
| 3.15E−01 | 6.09E+03 | 3.37E−01 | 3.61E+04 | 3.28E−01 | 1.77E+21 |
| 3.45E−01 | 6.09E+03 | 3.67E−01 | 3.61E+04 | 3.58E−01 | 1.85E+21 |
| 3.76E−01 | 6.53E+03 | 3.98E−01 | 3.56E+04 | 3.89E−01 | 1.97E+21 |
| 4.06E−01 | 6.42E+03 | 4.29E−01 | 3.55E+04 | 4.20E−01 | 2.18E+21 |
| 4.37E−01 | 6.36E+03 | 4.59E−01 | 3.50E+04 | 4.50E−01 | 2.13E+21 |
| 4.68E−01 | 6.31E+03 | 4.89E−01 | 3.48E+04 | 4.80E−01 | 2.24E+21 |
| 4.98E−01 | 6.57E+03 | 5.20E−01 | 3.49E+04 | 5.12E−01 | 2.36E+21 |
| 5.29E−01 | 6.59E+03 | 5.51E−01 | 3.37E+04 | 5.42E−01 | 2.40E+21 |
| 5.60E−01 | 6.69E+03 | 5.81E−01 | 3.37E+04 | 5.72E−01 | 2.52E+21 |
| 5.90E−01 | 6.74E+03 | 6.12E−01 | 3.33E+04 | 6.04E−01 | 2.66E+21 |
| 6.20E−01 | 6.69E+03 | 6.43E−01 | 3.34E+04 | 6.34E−01 | 2.70E+21 |
| 6.52E−01 | 6.66E+03 | 6.73E−01 | 3.32E+04 | 6.64E−01 | 2.79E+21 |
| 6.82E−01 | 7.00E+03 | 7.03E−01 | 3.34E+04 | 6.94E−01 | 2.75E+21 |
| 7.12E−01 | 7.08E+03 | 7.35E−01 | 3.24E+04 | 7.26E−01 | 2.96E+21 |
| 7.43E−01 | 6.94E+03 | 7.65E−01 | 3.23E+04 | 7.56E−01 | 2.96E+21 |
| 7.74E−01 | 7.17E+03 | 7.95E−01 | 3.22E+04 | 7.86E−01 | 2.98E+21 |
| 8.04E−01 | 7.08E+03 | 8.26E−01 | 3.23E+04 | 8.17E−01 | 3.00E+21 |
| 8.34E−01 | 7.08E+03 | 8.57E−01 | 3.18E+04 | 8.48E−01 | 3.09E+21 |
| 8.66E−01 | 7.19E+03 | 8.87E−01 | 3.13E+04 | 8.78E−01 | 3.21E+21 |
| 8.96E−01 | 7.16E+03 | 9.17E−01 | 3.17E+04 | 9.09E−01 | 3.21E+21 |
| 9.26E−01 | 7.40E+03 | 9.48E−01 | 3.07E+04 | 9.40E−01 | 3.25E+21 |
| 9.57E−01 | 7.40E+03 | 9.79E−01 | 3.02E+04 | 9.70E−01 | 3.17E+21 |
| 9.88E−01 | 7.27E+03 | 1.01E+00 | 3.05E+04 | 1.00E+00 | 3.35E+21 |
| 1.02E+00 | 7.68E+03 | 1.04E+00 | 3.06E+04 | 1.03E+00 | 3.22E+21 |
| 1.05E+00 | 7.54E+03 | 1.07E+00 | 2.96E+04 | 1.06E+00 | 3.36E+21 |
| 1.08E+00 | 7.78E+03 | 1.10E+00 | 2.94E+04 | 1.09E+00 | 3.20E+21 |
| 1.11E+00 | 7.85E+03 | 1.13E+00 | 2.93E+04 | 1.12E+00 | 3.28E+21 |
| 1.14E+00 | 7.75E+03 | 1.16E+00 | 2.88E+04 | 1.15E+00 | 3.14E+21 |
| 1.17E+00 | 7.89E+03 | 1.19E+00 | 2.84E+04 | 1.18E+00 | 3.28E+21 |
| 1.20E+00 | 8.02E+03 | 1.22E+00 | 2.79E+04 | 1.22E+00 | 3.42E+21 |
| 1.23E+00 | 8.14E+03 | 1.25E+00 | 2.81E+04 | 1.25E+00 | 3.24E+21 |
| 1.26E+00 | 8.19E+03 | 1.28E+00 | 2.73E+04 | 1.28E+00 | 3.22E+21 |
| 1.29E+00 | 8.23E+03 | 1.31E+00 | 2.73E+04 | 1.31E+00 | 3.15E+21 |
| 1.32E+00 | 8.31E+03 | 1.35E+00 | 2.72E+04 | 1.34E+00 | 3.17E+21 |
| 1.35E+00 | 8.51E+03 | 1.38E+00 | 2.63E+04 | 1.37E+00 | 3.15E+21 |
| 1.39E+00 | 8.57E+03 | 1.41E+00 | 2.62E+04 | 1.40E+00 | 3.08E+21 |
| 1.42E+00 | 8.77E+03 | 1.44E+00 | 2.57E+04 | 1.43E+00 | 3.04E+21 |
| 1.45E+00 | 8.56E+03 | 1.47E+00 | 2.57E+04 | 1.46E+00 | 3.10E+21 |
| 1.48E+00 | 8.72E+03 | 1.50E+00 | 2.50E+04 | 1.49E+00 | 3.07E+21 |
| 1.51E+00 | 8.80E+03 | 1.53E+00 | 2.50E+04 | 1.52E+00 | 2.97E+21 |
| 1.54E+00 | 8.97E+03 | 1.56E+00 | 2.46E+04 | 1.55E+00 | 2.91E+21 |
| 1.57E+00 | 9.03E+03 | 1.59E+00 | 2.36E+04 | 1.58E+00 | 2.92E+21 |
| 1.60E+00 | 9.27E+03 | 1.62E+00 | 2.32E+04 | 1.61E+00 | 2.97E+21 |
| 1.63E+00 | 9.59E+03 | 1.65E+00 | 2.35E+04 | 1.64E+00 | 2.87E+21 |
| 1.66E+00 | 9.87E+03 | 1.68E+00 | 2.30E+04 | 1.67E+00 | 2.87E+21 |
| 1.69E+00 | 1.01E+04 | 1.71E+00 | 2.25E+04 | 1.70E+00 | 2.96E+21 |
| 1.72E+00 | 9.88E+03 | 1.74E+00 | 2.20E+04 | 1.73E+00 | 2.73E+21 |
| 1.75E+00 | 1.02E+04 | 1.77E+00 | 2.16E+04 | 1.77E+00 | 2.65E+21 |
| 1.78E+00 | 1.05E+04 | 1.80E+00 | 2.09E+04 | 1.80E+00 | 2.63E+21 |
| 1.81E+00 | 1.06E+04 | 1.84E+00 | 2.06E+04 | 1.83E+00 | 2.54E+21 |
| 1.84E+00 | 1.08E+04 | 1.87E+00 | 2.01E+04 | 1.86E+00 | 2.52E+21 |
| 1.87E+00 | 1.13E+04 | 1.90E+00 | 1.94E+04 | 1.89E+00 | 2.40E+21 |
| 1.91E+00 | 1.16E+04 | 1.93E+00 | 1.90E+04 | 1.92E+00 | 2.41E+21 |
| 1.94E+00 | 1.19E+04 | 1.96E+00 | 1.85E+04 | 1.95E+00 | 2.34E+21 |
| 1.97E+00 | 1.19E+04 | 1.99E+00 | 1.79E+04 | 1.98E+00 | 2.30E+21 |
| 2.00E+00 | 1.18E+04 | 2.02E+00 | 1.71E+04 | 2.01E+00 | 2.20E+21 |
| 2.03E+00 | 1.24E+04 | 2.05E+00 | 1.66E+04 | 2.04E+00 | 2.19E+21 |
| 2.06E+00 | 1.28E+04 | 2.08E+00 | 1.65E+04 | 2.07E+00 | 2.18E+21 |
| 2.09E+00 | 1.29E+04 | 2.11E+00 | 1.59E+04 | 2.10E+00 | 2.05E+21 |
| 2.12E+00 | 1.38E+04 | 2.14E+00 | 1.51E+04 | 2.13E+00 | 2.00E+21 |
| 2.15E+00 | 1.40E+04 | 2.17E+00 | 1.45E+04 | 2.16E+00 | 1.97E+21 |
| 2.18E+00 | 1.42E+04 | 2.20E+00 | 1.41E+04 | 2.19E+00 | 1.84E+21 |
| 2.21E+00 | 1.46E+04 | 2.23E+00 | 1.38E+04 | 2.22E+00 | 1.86E+21 |
| 2.24E+00 | 1.51E+04 | 2.26E+00 | 1.28E+04 | 2.25E+00 | 1.68E+21 |
| 2.27E+00 | 1.57E+04 | 2.29E+00 | 1.21E+04 | 2.28E+00 | 1.67E+21 |
| 2.30E+00 | 1.57E+04 | 2.32E+00 | 1.17E+04 | 2.32E+00 | 1.62E+21 |
| 2.33E+00 | 1.59E+04 | 2.36E+00 | 1.12E+04 | 2.35E+00 | 1.64E+21 |
| 2.36E+00 | 1.65E+04 | 2.39E+00 | 1.05E+04 | 2.38E+00 | 1.51E+21 |
| 2.39E+00 | 1.70E+04 | 2.42E+00 | 9.83E+03 | 2.41E+00 | 1.44E+21 |
| 2.42E+00 | 1.76E+04 | 2.45E+00 | 9.63E+03 | 2.44E+00 | 1.37E+21 |
| 2.46E+00 | 1.78E+04 | 2.48E+00 | 8.72E+03 | 2.47E+00 | 1.24E+21 |
| 2.49E+00 | 1.82E+04 | 2.51E+00 | 8.21E+03 | 2.50E+00 | 1.27E+21 |
| 2.52E+00 | 1.85E+04 | 2.54E+00 | 7.79E+03 | 2.53E+00 | 1.11E+21 |
| 2.55E+00 | 1.84E+04 | 2.57E+00 | 7.21E+03 | 2.56E+00 | 1.14E+21 |
| 2.58E+00 | 1.86E+04 | 2.60E+00 | 6.81E+03 | 2.59E+00 | 1.06E+21 |
| 2.61E+00 | 1.91E+04 | 2.63E+00 | 6.33E+03 | 2.62E+00 | 9.53E+20 |
| 2.64E+00 | 1.91E+04 | 2.66E+00 | 5.89E+03 | 2.65E+00 | 9.34E+20 |
| 2.67E+00 | 1.93E+04 | 2.69E+00 | 5.65E+03 | 2.68E+00 | 8.81E+20 |
| 2.70E+00 | 2.00E+04 | 2.72E+00 | 5.17E+03 | 2.71E+00 | 8.28E+20 |
| 2.73E+00 | 1.97E+04 | 2.75E+00 | 4.71E+03 | 2.74E+00 | 8.17E+20 |
| 2.76E+00 | 1.98E+04 | 2.78E+00 | 4.33E+03 | 2.77E+00 | 6.91E+20 |
| 2.79E+00 | 2.02E+04 | 2.81E+00 | 4.05E+03 | 2.80E+00 | 7.37E+20 |
| 2.82E+00 | 2.00E+04 | 2.84E+00 | 3.63E+03 | 2.84E+00 | 6.17E+20 |
| 2.85E+00 | 2.03E+04 | 2.87E+00 | 3.45E+03 | 2.87E+00 | 5.57E+20 |
| 2.88E+00 | 2.03E+04 | 2.91E+00 | 3.26E+03 | 2.90E+00 | 6.14E+20 |
| 2.91E+00 | 2.02E+04 | 2.94E+00 | 2.89E+03 | 2.93E+00 | 5.35E+20 |
| 2.94E+00 | 2.00E+04 | 2.97E+00 | 2.65E+03 | 2.96E+00 | 5.16E+20 |
| 2.98E+00 | 2.00E+04 | 3.00E+00 | 2.45E+03 | 2.99E+00 | 4.55E+20 |
| 3.01E+00 | 2.02E+04 | 3.03E+00 | 2.43E+03 | 3.02E+00 | 4.58E+20 |
| 3.04E+00 | 2.01E+04 | 3.06E+00 | 2.12E+03 | 3.05E+00 | 3.67E+20 |
| 3.07E+00 | 1.97E+04 | 3.09E+00 | 1.94E+03 | 3.08E+00 | 3.39E+20 |
| 3.10E+00 | 1.97E+04 | 3.12E+00 | 1.72E+03 | 3.11E+00 | 3.69E+20 |
| 3.13E+00 | 2.01E+04 | 3.15E+00 | 1.65E+03 | 3.14E+00 | 3.46E+20 |
| 3.16E+00 | 1.98E+04 | 3.18E+00 | 1.45E+03 | 3.17E+00 | 3.23E+20 |
| 3.19E+00 | 2.00E+04 | 3.21E+00 | 1.32E+03 | 3.20E+00 | 2.75E+20 |
| 3.22E+00 | 1.98E+04 | 3.24E+00 | 1.15E+03 | 3.23E+00 | 2.78E+20 |
| 3.25E+00 | 1.99E+04 | 3.27E+00 | 1.20E+03 | 3.26E+00 | 2.58E+20 |
| 3.28E+00 | 1.96E+04 | 3.30E+00 | 1.11E+03 | 3.29E+00 | 2.58E+20 |
| 3.31E+00 | 1.94E+04 | 3.33E+00 | 1.01E+03 | 3.33E+00 | 2.56E+20 |
| 3.34E+00 | 1.94E+04 | 3.36E+00 | 9.33E+02 | 3.36E+00 | 1.79E+20 |
| 3.37E+00 | 1.93E+04 | 3.39E+00 | 7.80E+02 | 3.39E+00 | 2.31E+20 |
| 3.40E+00 | 1.96E+04 | 3.42E+00 | 7.48E+02 | 3.42E+00 | 1.70E+20 |
| 3.43E+00 | 1.96E+04 | 3.46E+00 | 6.87E+02 | 3.45E+00 | 1.74E+20 |
| 3.46E+00 | 1.92E+04 | 3.49E+00 | 6.18E+02 | 3.48E+00 | 1.89E+20 |
| 3.50E+00 | 1.93E+04 | 3.52E+00 | 5.68E+02 | 3.51E+00 | 1.20E+20 |
| 3.53E+00 | 1.91E+04 | 3.55E+00 | 5.46E+02 | 3.54E+00 | 1.67E+20 |
| 3.56E+00 | 1.91E+04 | 3.58E+00 | 5.67E+02 | 3.57E+00 | 1.46E+20 |
| 3.59E+00 | 1.91E+04 | 3.61E+00 | 5.19E+02 | 3.60E+00 | 1.26E+20 |
| 3.62E+00 | 1.93E+04 | 3.64E+00 | 5.26E+02 | 3.63E+00 | 1.12E+20 |
| 3.65E+00 | 1.93E+04 | 3.67E+00 | 4.48E+02 | 3.66E+00 | 1.12E+20 |
| 3.68E+00 | 1.90E+04 | 3.70E+00 | 4.67E+02 | 3.69E+00 | 1.33E+20 |
| 3.71E+00 | 1.90E+04 | 3.73E+00 | 4.01E+02 | 3.72E+00 | 8.48E+19 |
| 3.74E+00 | 1.89E+04 | 3.76E+00 | 3.85E+02 | 3.75E+00 | 9.30E+19 |
| 3.77E+00 | 1.90E+04 | 3.79E+00 | 3.34E+02 | 3.78E+00 | 1.09E+20 |
| 3.80E+00 | 1.89E+04 | 3.82E+00 | 3.34E+02 | 3.81E+00 | 8.07E+19 |
| 3.83E+00 | 1.87E+04 | 3.85E+00 | 2.73E+02 | 3.84E+00 | 1.12E+20 |
| 3.86E+00 | 1.92E+04 | 3.88E+00 | 3.07E+02 | 3.88E+00 | 7.52E+19 |
| 3.89E+00 | 1.85E+04 | 3.91E+00 | 2.42E+02 | 3.91E+00 | 9.71E+19 |
| 3.92E+00 | 1.87E+04 | 3.94E+00 | 2.86E+02 | 3.94E+00 | 6.98E+19 |
| 3.95E+00 | 1.87E+04 | 3.98E+00 | 2.29E+02 | 3.97E+00 | 7.52E+19 |
| 3.98E+00 | 1.88E+04 | 4.01E+00 | 2.08E+02 | 4.00E+00 | 7.66E+19 |
| 4.02E+00 | 1.92E+04 | 4.04E+00 | 2.46E+02 | 4.03E+00 | 8.07E+19 |
| 4.05E+00 | 1.87E+04 | 4.07E+00 | 2.27E+02 | 4.06E+00 | 6.56E+19 |
| 4.08E+00 | 1.93E+04 | 4.10E+00 | 2.10E+02 | 4.09E+00 | 5.88E+19 |
| 4.11E+00 | 1.90E+04 | 4.13E+00 | 1.62E+02 | 4.12E+00 | 8.21E+19 |
| 4.14E+00 | 1.89E+04 | 4.16E+00 | 1.68E+02 | 4.15E+00 | 7.39E+19 |
| 4.17E+00 | 1.89E+04 | 4.19E+00 | 1.51E+02 | 4.18E+00 | 6.56E+19 |
| 4.20E+00 | 1.91E+04 | 4.22E+00 | 1.51E+02 | 4.21E+00 | 6.98E+19 |
| 4.23E+00 | 1.91E+04 | 4.25E+00 | 1.75E+02 | 4.24E+00 | 6.70E+19 |
| 4.26E+00 | 1.89E+04 | 4.28E+00 | 1.24E+02 | 4.27E+00 | 7.39E+19 |
| 4.29E+00 | 1.92E+04 | 4.31E+00 | 1.47E+02 | 4.30E+00 | 3.83E+19 |
| 4.32E+00 | 1.90E+04 | 4.34E+00 | 1.43E+02 | 4.33E+00 | 6.43E+19 |
| 4.35E+00 | 1.91E+04 | 4.37E+00 | 1.37E+02 | 4.36E+00 | 5.20E+19 |
| 4.38E+00 | 1.90E+04 | 4.40E+00 | 1.34E+02 | 4.39E+00 | 5.74E+19 |
| 4.41E+00 | 1.91E+04 | 4.43E+00 | 1.13E+02 | 4.43E+00 | 5.06E+19 |
| 4.44E+00 | 1.90E+04 | 4.47E+00 | 1.05E+02 | 4.46E+00 | 3.56E+19 |
| 4.47E+00 | 1.96E+04 | 4.50E+00 | 1.01E+02 | 4.49E+00 | 5.20E+19 |
| 4.50E+00 | 1.93E+04 | 4.53E+00 | 1.01E+02 | 4.52E+00 | 5.74E+19 |
| 4.53E+00 | 1.92E+04 | 4.56E+00 | 1.13E+02 | 4.55E+00 | 5.20E+19 |
| 4.57E+00 | 1.91E+04 | 4.59E+00 | 1.07E+02 | 4.58E+00 | 4.24E+19 |
| 4.60E+00 | 1.94E+04 | 4.62E+00 | 9.92E+01 | 4.61E+00 | 4.65E+19 |
| 4.63E+00 | 1.95E+04 | 4.65E+00 | 7.25E+01 | 4.64E+00 | 5.47E+19 |
| 4.66E+00 | 1.93E+04 | 4.68E+00 | 9.16E+01 | 4.67E+00 | 3.56E+19 |
| 4.69E+00 | 1.94E+04 | 4.71E+00 | 6.87E+01 | 4.70E+00 | 4.65E+19 |
| 4.72E+00 | 1.95E+04 | 4.74E+00 | 7.44E+01 | 4.73E+00 | 4.92E+19 |
| 4.75E+00 | 1.90E+04 | 4.77E+00 | 1.11E+02 | 4.76E+00 | 4.38E+19 |
| 4.78E+00 | 1.94E+04 | 4.80E+00 | 5.15E+01 | 4.79E+00 | 3.56E+19 |
| 4.81E+00 | 1.93E+04 | 4.83E+00 | 8.39E+01 | 4.82E+00 | 3.28E+19 |
| 4.84E+00 | 1.96E+04 | 4.86E+00 | 6.87E+01 | 4.85E+00 | 5.06E+19 |
| 4.87E+00 | 1.94E+04 | 4.89E+00 | 5.91E+01 | 4.88E+00 | 5.33E+19 |
| 4.90E+00 | 1.95E+04 | 4.92E+00 | 6.68E+01 | 4.91E+00 | 6.15E+19 |
| 4.93E+00 | 1.96E+04 | 4.95E+00 | 8.01E+01 | 4.95E+00 | 4.24E+19 |
| 4.96E+00 | 1.95E+04 | 4.98E+00 | 7.25E+01 | 4.98E+00 | 3.83E+19 |
| 4.99E+00 | 1.93E+04 | 5.02E+00 | 7.06E+01 | 5.01E+00 | 3.28E+19 |
| 5.02E+00 | 1.95E+04 | 5.05E+00 | 6.87E+01 | 5.04E+00 | 3.56E+19 |
| 5.05E+00 | 1.99E+04 | 5.08E+00 | 6.68E+01 | 5.07E+00 | 2.87E+19 |
| 5.09E+00 | 1.99E+04 | 5.11E+00 | 4.96E+01 | 5.10E+00 | 2.05E+19 |
| 5.12E+00 | 1.96E+04 | 5.14E+00 | 5.15E+01 | 5.13E+00 | 3.01E+19 |
| 5.15E+00 | 2.03E+04 | 5.17E+00 | 5.72E+01 | 5.16E+00 | 3.15E+19 |
| 5.18E+00 | 2.00E+04 | 5.20E+00 | 5.91E+01 | 5.19E+00 | 4.24E+19 |
| 5.21E+00 | 1.98E+04 | 5.23E+00 | 4.77E+01 | 5.22E+00 | 3.28E+19 |
| 5.24E+00 | 1.99E+04 | 5.26E+00 | 5.53E+01 | 5.25E+00 | 3.01E+19 |
| 5.27E+00 | 2.00E+04 | 5.29E+00 | 4.77E+01 | 5.28E+00 | 3.42E+19 |
| 5.30E+00 | 2.01E+04 | 5.32E+00 | 6.29E+01 | 5.31E+00 | 3.15E+19 |
| 5.33E+00 | 2.01E+04 | 5.35E+00 | 5.91E+01 | 5.34E+00 | 3.56E+19 |
| 5.36E+00 | 2.04E+04 | 5.38E+00 | 4.39E+01 | 5.37E+00 | 2.60E+19 |
| 5.39E+00 | 1.98E+04 | 5.41E+00 | 3.05E+01 | 5.40E+00 | 3.28E+19 |
| 5.42E+00 | 2.02E+04 | 5.44E+00 | 4.20E+01 | 5.43E+00 | 5.06E+19 |
| 5.45E+00 | 2.04E+04 | 5.47E+00 | 4.58E+01 | 5.47E+00 | 1.91E+19 |
| 5.48E+00 | 2.03E+04 | 5.50E+00 | 2.86E+01 | 5.50E+00 | 3.56E+19 |
| 5.51E+00 | 2.03E+04 | 5.53E+00 | 4.96E+01 | 5.53E+00 | 1.91E+19 |
| 5.54E+00 | 2.03E+04 | 5.57E+00 | 4.77E+01 | 5.56E+00 | 3.28E+19 |
| 5.57E+00 | 2.03E+04 | 5.60E+00 | 3.43E+01 | 5.59E+00 | 3.28E+19 |
| 5.61E+00 | 2.04E+04 | 5.63E+00 | 2.29E+01 | 5.62E+00 | 2.33E+19 |
| 5.64E+00 | 2.06E+04 | 5.66E+00 | 4.96E+01 | 5.65E+00 | 2.74E+19 |
| 5.67E+00 | 2.05E+04 | 5.69E+00 | 3.62E+01 | 5.68E+00 | 2.46E+19 |
| 5.70E+00 | 2.01E+04 | 5.72E+00 | 3.05E+01 | 5.71E+00 | 2.74E+19 |
| 5.73E+00 | 2.01E+04 | 5.75E+00 | 4.58E+01 | 5.74E+00 | 2.60E+19 |
| 5.76E+00 | 2.02E+04 | 5.78E+00 | 2.86E+01 | 5.77E+00 | 3.56E+19 |
| 5.79E+00 | 2.03E+04 | 5.81E+00 | 4.01E+01 | 5.80E+00 | 3.42E+19 |
| 5.82E+00 | 2.02E+04 | 5.84E+00 | 3.05E+01 | 5.83E+00 | 3.69E+19 |
| 5.85E+00 | 2.06E+04 | 5.87E+00 | 3.62E+01 | 5.86E+00 | 2.19E+19 |
| 5.88E+00 | 2.11E+04 | 5.90E+00 | 2.48E+01 | 5.89E+00 | 2.05E+19 |
| 5.91E+00 | 2.11E+04 | 5.93E+00 | 3.24E+01 | 5.92E+00 | 2.19E+19 |
| 5.94E+00 | 2.03E+04 | 5.96E+00 | 2.67E+01 | 5.95E+00 | 3.01E+19 |
| 5.97E+00 | 2.11E+04 | 5.99E+00 | 1.91E+01 | 5.99E+00 | 2.60E+19 |
| 6.00E+00 | 2.06E+04 | 6.02E+00 | 1.14E+01 | 6.02E+00 | 2.19E+19 |
| 6.03E+00 | 2.06E+04 | 6.05E+00 | 4.01E+01 | 6.05E+00 | 1.64E+19 |
| 6.06E+00 | 2.08E+04 | 6.09E+00 | 2.29E+01 | 6.08E+00 | 2.33E+19 |
| 6.09E+00 | 2.08E+04 | 6.12E+00 | 2.29E+01 | 6.11E+00 | 2.05E+19 |
| 6.13E+00 | 2.07E+04 | 6.15E+00 | 3.05E+01 | 6.14E+00 | 2.19E+19 |
| 6.16E+00 | 2.07E+04 | 6.18E+00 | 1.91E+01 | 6.17E+00 | 2.60E+19 |
| 6.19E+00 | 2.06E+04 | 6.21E+00 | 3.43E+01 | 6.20E+00 | 2.33E+19 |
| 6.22E+00 | 2.11E+04 | 6.24E+00 | 2.67E+01 | 6.23E+00 | 2.74E+19 |
| 6.25E+00 | 2.06E+04 | 6.27E+00 | 2.48E+01 | 6.26E+00 | 2.05E+19 |
| 6.28E+00 | 2.12E+04 | 6.30E+00 | 2.10E+01 | 6.29E+00 | 2.60E+19 |
| 6.31E+00 | 2.11E+04 | 6.33E+00 | 2.10E+01 | 6.32E+00 | 1.78E+19 |
| 6.34E+00 | 2.10E+04 | 6.36E+00 | 1.34E+01 | 6.35E+00 | 6.84E+18 |
| 6.37E+00 | 2.12E+04 | 6.39E+00 | 1.53E+01 | 6.38E+00 | 3.28E+19 |
| 6.40E+00 | 2.12E+04 | 6.42E+00 | 2.29E+01 | 6.41E+00 | 2.05E+19 |
| 6.43E+00 | 2.14E+04 | 6.45E+00 | 1.72E+01 | 6.44E+00 | 2.60E+19 |
| 6.46E+00 | 2.10E+04 | 6.48E+00 | 1.72E+01 | 6.47E+00 | 2.60E+19 |
| 6.49E+00 | 2.13E+04 | 6.51E+00 | 2.48E+01 | 6.50E+00 | 1.50E+19 |
| 6.52E+00 | 2.11E+04 | 6.54E+00 | 2.86E+01 | 6.54E+00 | 2.46E+19 |
| 6.55E+00 | 2.15E+04 | 6.58E+00 | 1.53E+01 | 6.57E+00 | 9.57E+18 |
| 6.58E+00 | 2.11E+04 | 6.61E+00 | 1.14E+01 | 6.60E+00 | 1.64E+19 |
| 6.61E+00 | 2.12E+04 | 6.64E+00 | 1.53E+01 | 6.63E+00 | 2.05E+19 |
| 6.64E+00 | 2.12E+04 | 6.67E+00 | 9.54E+00 | 6.66E+00 | 1.91E+19 |
| 6.68E+00 | 2.12E+04 | 6.70E+00 | 1.34E+01 | 6.69E+00 | 1.23E+19 |
| 6.71E+00 | 2.17E+04 | 6.73E+00 | 1.14E+01 | 6.72E+00 | 1.50E+19 |
| 6.74E+00 | 2.13E+04 | 6.76E+00 | 1.34E+01 | 6.75E+00 | 2.60E+19 |
| 6.77E+00 | 2.13E+04 | 6.79E+00 | 1.53E+01 | 6.78E+00 | 8.21E+18 |
| 6.80E+00 | 2.16E+04 | 6.82E+00 | 3.24E+01 | 6.81E+00 | 1.91E+19 |
| 6.83E+00 | 2.11E+04 | 6.85E+00 | 1.72E+01 | 6.84E+00 | 1.91E+19 |
| 6.86E+00 | 2.17E+04 | 6.88E+00 | 1.53E+01 | 6.87E+00 | 2.05E+19 |
| 6.89E+00 | 2.12E+04 | 6.91E+00 | 1.14E+01 | 6.90E+00 | 1.78E+19 |
| 6.92E+00 | 2.11E+04 | 6.94E+00 | 1.53E+01 | 6.93E+00 | 2.46E+19 |
| 6.95E+00 | 2.19E+04 | 6.97E+00 | 1.53E+01 | 6.96E+00 | 3.15E+19 |
| 6.98E+00 | 2.16E+04 | 7.00E+00 | 1.53E+01 | 6.99E+00 | 1.78E+19 |
| 7.01E+00 | 2.16E+04 | 7.03E+00 | 9.54E+00 | 7.02E+00 | 2.33E+19 |
| 7.04E+00 | 2.17E+04 | 7.06E+00 | 1.34E+01 | 7.06E+00 | 1.78E+19 |
| 7.07E+00 | 2.18E+04 | 7.09E+00 | 9.54E+00 | 7.09E+00 | 1.78E+19 |
| 7.10E+00 | 2.18E+04 | 7.13E+00 | 9.54E+00 | 7.12E+00 | 1.09E+19 |
| 7.13E+00 | 2.17E+04 | 7.16E+00 | 1.53E+01 | 7.15E+00 | 1.09E+19 |
| 7.16E+00 | 2.15E+04 | 7.19E+00 | 2.86E+01 | 7.18E+00 | 2.19E+19 |
| 7.19E+00 | 2.14E+04 | 7.22E+00 | 1.72E+01 | 7.21E+00 | 1.37E+19 |
| 7.23E+00 | 2.19E+04 | 7.25E+00 | 1.34E+01 | 7.24E+00 | 2.33E+19 |
| 7.26E+00 | 2.17E+04 | 7.28E+00 | 1.14E+01 | 7.27E+00 | 1.91E+19 |
| 7.29E+00 | 2.14E+04 | 7.31E+00 | 2.10E+01 | 7.30E+00 | 2.19E+19 |
| 7.32E+00 | 2.17E+04 | 7.34E+00 | 5.72E+00 | 7.33E+00 | 1.50E+19 |
| 7.35E+00 | 2.18E+04 | 7.37E+00 | 2.48E+01 | 7.36E+00 | 1.78E+19 |
| 7.38E+00 | 2.18E+04 | 7.40E+00 | 5.72E+00 | 7.39E+00 | 1.50E+19 |
| 7.41E+00 | 2.18E+04 | 7.43E+00 | 1.34E+01 | 7.42E+00 | 2.05E+19 |
| 7.44E+00 | 2.15E+04 | 7.46E+00 | 1.14E+01 | 7.45E+00 | 1.50E+19 |
| 7.47E+00 | 2.22E+04 | 7.49E+00 | 2.29E+01 | 7.48E+00 | 1.64E+19 |
| 7.50E+00 | 2.19E+04 | 7.52E+00 | 1.53E+01 | 7.51E+00 | 9.57E+18 |
| 7.53E+00 | 2.18E+04 | 7.55E+00 | 9.54E+00 | 7.54E+00 | 1.09E+19 |
| 7.56E+00 | 2.21E+04 | 7.58E+00 | 1.14E+01 | 7.58E+00 | 9.57E+18 |
| 7.59E+00 | 2.19E+04 | 7.61E+00 | 7.63E+00 | 7.61E+00 | 9.57E+18 |
| 7.62E+00 | 2.20E+04 | 7.65E+00 | 2.10E+01 | 7.64E+00 | 1.23E+19 |
| 7.65E+00 | 2.23E+04 | 7.68E+00 | 1.91E+00 | 7.67E+00 | 1.09E+19 |
| 7.68E+00 | 2.18E+04 | 7.71E+00 | 1.91E+01 | 7.70E+00 | 1.23E+19 |
| 7.72E+00 | 2.22E+04 | 7.74E+00 | 7.63E+00 | 7.73E+00 | 5.47E+18 |
| 7.75E+00 | 2.23E+04 | 7.77E+00 | 9.54E+00 | 7.76E+00 | 1.09E+19 |
| 7.78E+00 | 2.22E+04 | 7.80E+00 | 1.14E+01 | 7.79E+00 | 1.09E+19 |
| 7.81E+00 | 2.23E+04 | 7.83E+00 | 5.72E+00 | 7.82E+00 | 1.23E+19 |
| 7.84E+00 | 2.24E+04 | 7.86E+00 | 1.53E+01 | 7.85E+00 | 1.23E+19 |
| 7.87E+00 | 2.23E+04 | 7.89E+00 | 1.34E+01 | 7.88E+00 | 8.21E+18 |
| 7.90E+00 | 2.21E+04 | 7.92E+00 | 5.72E+00 | 7.91E+00 | 1.64E+19 |
| 7.93E+00 | 2.26E+04 | 7.95E+00 | 5.72E+00 | 7.94E+00 | 9.57E+18 |
| 7.96E+00 | 2.27E+04 | 7.98E+00 | 9.54E+00 | 7.97E+00 | 1.64E+19 |
| 7.99E+00 | 2.26E+04 | 8.01E+00 | 1.34E+01 | 8.00E+00 | 1.64E+19 |
| 8.02E+00 | 2.23E+04 | 8.04E+00 | 1.53E+01 | 8.03E+00 | 1.64E+19 |
| 8.05E+00 | 2.18E+04 | 8.07E+00 | 9.54E+00 | 8.06E+00 | 8.21E+18 |
| 8.08E+00 | 2.22E+04 | 8.10E+00 | 5.72E+00 | 8.10E+00 | 5.47E+18 |
| 8.11E+00 | 2.23E+04 | 8.13E+00 | 9.54E+00 | 8.13E+00 | 1.64E+19 |
| 8.14E+00 | 2.28E+04 | 8.16E+00 | 1.14E+01 | 8.16E+00 | 1.50E+19 |
| 8.17E+00 | 2.27E+04 | 8.20E+00 | 3.81E+00 | 8.19E+00 | 6.84E+18 |
| 8.20E+00 | 2.26E+04 | 8.23E+00 | 5.72E+00 | 8.22E+00 | 1.23E+19 |
| 8.24E+00 | 2.27E+04 | 8.26E+00 | 9.54E+00 | 8.25E+00 | 9.57E+18 |
| 8.27E+00 | 2.26E+04 | 8.29E+00 | 1.14E+01 | 8.28E+00 | 1.37E+19 |
| 8.30E+00 | 2.27E+04 | 8.32E+00 | 9.54E+00 | 8.31E+00 | 1.78E+19 |
| 8.33E+00 | 2.22E+04 | 8.35E+00 | 1.14E+01 | 8.34E+00 | 8.21E+18 |
| 8.36E+00 | 2.29E+04 | 8.38E+00 | 3.81E+00 | 8.37E+00 | 1.23E+19 |
| 8.39E+00 | 2.25E+04 | 8.41E+00 | 3.81E+00 | 8.40E+00 | 9.57E+18 |
| 8.42E+00 | 2.23E+04 | 8.44E+00 | 7.63E+00 | 8.43E+00 | 1.23E+19 |
| 8.45E+00 | 2.27E+04 | 8.47E+00 | 5.72E+00 | 8.46E+00 | 9.57E+18 |
| 8.48E+00 | 2.26E+04 | 8.50E+00 | 3.81E+00 | 8.49E+00 | 4.10E+18 |
| 8.51E+00 | 2.25E+04 | 8.53E+00 | 3.81E+00 | 8.52E+00 | 1.37E+19 |
| 8.54E+00 | 2.24E+04 | 8.56E+00 | 9.54E+00 | 8.55E+00 | 8.21E+18 |
| 8.57E+00 | 2.25E+04 | 8.59E+00 | 1.14E+01 | 8.58E+00 | 8.21E+18 |
| 8.60E+00 | 2.27E+04 | 8.62E+00 | 3.81E+00 | 8.61E+00 | 6.84E+18 |
| 8.63E+00 | 2.25E+04 | 8.65E+00 | 3.81E+00 | 8.65E+00 | 5.47E+18 |
| 8.66E+00 | 2.27E+04 | 8.68E+00 | 7.63E+00 | 8.68E+00 | 9.57E+18 |
| 8.69E+00 | 2.26E+04 | 8.72E+00 | 5.72E+00 | 8.71E+00 | 1.23E+19 |
| 8.72E+00 | 2.31E+04 | 8.75E+00 | 3.81E+00 | 8.74E+00 | 1.09E+19 |
| 8.75E+00 | 2.30E+04 | 8.78E+00 | 1.91E+00 | 8.77E+00 | 1.09E+19 |
| 8.79E+00 | 2.26E+04 | 8.81E+00 | 7.63E+00 | 8.80E+00 | 5.47E+18 |
| 8.82E+00 | 2.30E+04 | 8.84E+00 | 1.91E+00 | 8.83E+00 | 1.91E+19 |
| 8.85E+00 | 2.29E+04 | 8.87E+00 | 7.63E+00 | 8.86E+00 | 6.84E+18 |
| 8.88E+00 | 2.29E+04 | 8.90E+00 | 7.63E+00 | 8.89E+00 | 6.84E+18 |
| 8.91E+00 | 2.28E+04 | 8.93E+00 | 5.72E−01 | 8.92E+00 | 1.23E+19 |
| 8.94E+00 | 2.30E+04 | 8.96E+00 | 5.72E+00 | 8.95E+00 | 6.84E+18 |
| 8.97E+00 | 2.33E+04 | 8.99E+00 | 3.81E+00 | 8.98E+00 | 5.47E+18 |
| 9.00E+00 | 2.28E+04 | 9.02E+00 | 3.81E+00 | 9.01E+00 | 1.78E+19 |
| 9.03E+00 | 2.31E+04 | 9.05E+00 | 9.54E+00 | 9.04E+00 | 1.50E+19 |
| 9.06E+00 | 2.32E+04 | 9.08E+00 | 7.63E+00 | 9.07E+00 | 1.23E+19 |
| 9.09E+00 | 2.29E+04 | 9.11E+00 | 3.81E+00 | 9.10E+00 | 9.57E+18 |
| 9.12E+00 | 2.32E+04 | 9.14E+00 | 3.81E+00 | 9.13E+00 | 5.47E+18 |
| 9.15E+00 | 2.25E+04 | 9.17E+00 | 9.54E+00 | 9.16E+00 | 1.09E+19 |
| 9.18E+00 | 2.31E+04 | 9.21E+00 | 5.72E−01 | 9.20E+00 | 4.10E+18 |
| 9.21E+00 | 2.30E+04 | 9.24E+00 | 5.72E−01 | 9.23E+00 | 1.50E+19 |
| 9.24E+00 | 2.27E+04 | 9.27E+00 | 3.81E+00 | 9.26E+00 | 1.23E+19 |
| 9.27E+00 | 2.34E+04 | 9.30E+00 | 7.63E+00 | 9.29E+00 | 1.50E+19 |
| 9.30E+00 | 2.33E+04 | 9.33E+00 | 1.91E+00 | 9.32E+00 | 1.37E+19 |
| 9.34E+00 | 2.34E+04 | 9.36E+00 | 9.54E+00 | 9.35E+00 | 9.57E+18 |
| 9.37E+00 | 2.35E+04 | 9.39E+00 | 5.72E+00 | 9.38E+00 | 9.57E+18 |
| 9.40E+00 | 2.31E+04 | 9.42E+00 | 3.81E+00 | 9.41E+00 | 1.37E+18 |
| 9.43E+00 | 2.33E+04 | 9.45E+00 | 5.72E−01 | 9.44E+00 | 8.21E+18 |
| 9.46E+00 | 2.33E+04 | 9.48E+00 | 3.81E+00 | 9.47E+00 | 5.47E+18 |
| 9.49E+00 | 2.29E+04 | 9.51E+00 | 5.72E+00 | 9.50E+00 | 5.47E+18 |
| 9.52E+00 | 2.30E+04 | 9.54E+00 | 5.72E+00 | 9.53E+00 | 6.84E+18 |
| 9.55E+00 | 2.34E+04 | 9.57E+00 | 5.72E+00 | 9.56E+00 | 1.09E+19 |
| 9.58E+00 | 2.30E+04 | 9.60E+00 | 1.91E+00 | 9.59E+00 | 9.57E+18 |
| 9.61E+00 | 2.31E+04 | 9.63E+00 | 1.91E+00 | 9.62E+00 | 4.10E+18 |
| 9.64E+00 | 2.32E+04 | 9.66E+00 | 3.81E+00 | 9.65E+00 | 1.37E+19 |
| 9.67E+00 | 2.32E+04 | 9.69E+00 | 1.91E+00 | 9.69E+00 | 2.74E+18 |
| 9.70E+00 | 2.30E+04 | 9.72E+00 | 3.81E+00 | 9.72E+00 | 1.37E+19 |
| 9.73E+00 | 2.31E+04 | 9.76E+00 | 5.72E+00 | 9.75E+00 | 1.09E+19 |
| 9.76E+00 | 2.37E+04 | 9.79E+00 | 3.81E+00 | 9.78E+00 | 5.47E+18 |
| 9.79E+00 | 2.35E+04 | 9.82E+00 | 5.72E+00 | 9.81E+00 | 4.10E+18 |
| 9.83E+00 | 2.33E+04 | 9.85E+00 | 3.81E+00 | 9.84E+00 | 5.47E+18 |
| 9.86E+00 | 2.30E+04 | 9.88E+00 | 1.91E+00 | 9.87E+00 | 6.84E+18 |
| 9.89E+00 | 2.34E+04 | 9.91E+00 | 7.63E+00 | 9.90E+00 | 6.84E+18 |
| 9.92E+00 | 2.35E+04 | 9.94E+00 | 3.81E+00 | 9.93E+00 | 5.47E+18 |
| 9.95E+00 | 2.32E+04 | 9.97E+00 | 1.14E+01 | 9.96E+00 | 5.47E+18 |
| 9.98E+00 | 2.31E+04 | 1.00E+01 | 3.81E+00 | 9.99E+00 | 8.21E+18 |
| 1.00E+01 | 2.37E+04 | 1.00E+01 | 1.91E+00 | 1.00E+01 | 2.74E+18 |
| 1.00E+01 | 2.38E+04 | 1.01E+01 | 1.91E+00 | 1.01E+01 | 5.47E+18 |
| 1.01E+01 | 2.38E+04 | 1.01E+01 | 5.72E+00 | 1.01E+01 | 1.09E+19 |
| 1.01E+01 | 2.38E+04 | 1.01E+01 | 3.81E+00 | 1.01E+01 | 6.84E+18 |
| 1.01E+01 | 2.36E+04 | 1.02E+01 | 5.72E−01 | 1.01E+01 | 8.21E+18 |
| 1.02E+01 | 2.38E+04 | 1.02E+01 | 5.72E−01 | 1.02E+01 | 4.10E+17 |
| 1.02E+01 | 2.36E+04 | 1.02E+01 | 1.91E+00 | 1.02E+01 | 9.57E+18 |
| 1.02E+01 | 2.33E+04 | 1.02E+01 | 9.54E+00 | 1.02E+01 | 5.47E+18 |
| 1.03E+01 | 2.36E+04 | 1.03E+01 | 3.81E+00 | 1.03E+01 | 6.84E+18 |
| 1.03E+01 | 2.30E+04 | 1.03E+01 | 1.91E+00 | 1.03E+01 | 8.21E+18 |
| 1.03E+01 | 2.34E+04 | 1.03E+01 | 1.91E+00 | 1.03E+01 | 4.10E+18 |
| 1.03E+01 | 2.36E+04 | 1.04E+01 | 3.81E+00 | 1.04E+01 | 4.10E+17 |
| 1.04E+01 | 2.34E+04 | 1.04E+01 | 1.91E+00 | 1.04E+01 | 1.37E+18 |
| 1.04E+01 | 2.36E+04 | 1.04E+01 | 5.72E+00 | 1.04E+01 | 4.10E+17 |
| 1.04E+01 | 2.36E+04 | 1.05E+01 | 1.91E+00 | 1.04E+01 | 4.10E+18 |
| 1.05E+01 | 2.41E+04 | 1.05E+01 | 3.81E+00 | 1.05E+01 | 4.10E+18 |
| 1.05E+01 | 2.37E+04 | 1.05E+01 | 5.72E−01 | 1.05E+01 | 5.47E+18 |
| 1.05E+01 | 2.38E+04 | 1.06E+01 | 3.81E+00 | 1.05E+01 | 6.84E+18 |
| 1.06E+01 | 2.37E+04 | 1.06E+01 | 1.91E+00 | 1.06E+01 | 4.10E+18 |
| 1.06E+01 | 2.40E+04 | 1.06E+01 | 5.72E−01 | 1.06E+01 | 1.37E+18 |
| 1.06E+01 | 2.41E+04 | 1.06E+01 | 5.72E+00 | 1.06E+01 | 8.21E+18 |
| 1.07E+01 | 2.37E+04 | 1.07E+01 | 5.72E−01 | 1.07E+01 | 4.10E+18 |
| 1.07E+01 | 2.38E+04 | 1.07E+01 | 3.81E+00 | 1.07E+01 | 1.23E+19 |
| 1.07E+01 | 2.43E+04 | 1.07E+01 | 1.91E+00 | 1.07E+01 | 2.74E+18 |
| 1.07E+01 | 2.40E+04 | 1.08E+01 | 1.91E+00 | 1.08E+01 | 8.21E+18 |
| 1.08E+01 | 2.40E+04 | 1.08E+01 | 1.91E+00 | 1.08E+01 | 1.37E+18 |
| 1.08E+01 | 2.38E+04 | 1.08E+01 | 5.72E−01 | 1.08E+01 | 9.57E+18 |
| 1.08E+01 | 2.40E+04 | 1.09E+01 | 1.91E+00 | 1.08E+01 | 4.10E+18 |
| 1.09E+01 | 2.42E+04 | 1.09E+01 | 1.91E+00 | 1.09E+01 | 5.47E+18 |
| 1.09E+01 | 2.41E+04 | 1.09E+01 | 1.91E+00 | 1.09E+01 | 4.10E+18 |
| 1.09E+01 | 2.41E+04 | 1.09E+01 | 5.72E+00 | 1.09E+01 | 6.84E+18 |
| 1.10E+01 | 2.35E+04 | 1.10E+01 | 1.91E+00 | 1.10E+01 | 6.84E+18 |
| 1.10E+01 | 2.39E+04 | 1.10E+01 | 5.72E−01 | 1.10E+01 | 6.84E+18 |
| 1.10E+01 | 2.36E+04 | 1.10E+01 | 1.91E+00 | 1.10E+01 | 4.10E+18 |
| 1.10E+01 | 2.34E+04 | 1.11E+01 | 5.72E−01 | 1.11E+01 | 6.84E+18 |
| 1.11E+01 | 2.41E+04 | 1.11E+01 | 3.81E+00 | 1.11E+01 | 5.47E+18 |
| 1.11E+01 | 2.36E+04 | 1.11E+01 | 1.91E+00 | 1.11E+01 | 2.74E+18 |
| 1.11E+01 | 2.35E+04 | 1.12E+01 | 1.91E+00 | 1.12E+01 | 4.10E+17 |
| 1.12E+01 | 2.41E+04 | 1.12E+01 | 1.91E+00 | 1.12E+01 | 4.10E+18 |
| 1.12E+01 | 2.38E+04 | 1.12E+01 | 1.91E+00 | 1.12E+01 | 1.37E+18 |
| 1.12E+01 | 2.36E+04 | 1.13E+01 | 5.72E+00 | 1.12E+01 | 4.10E+18 |
| 1.13E+01 | 2.41E+04 | 1.13E+01 | 1.91E+00 | 1.13E+01 | 2.74E+18 |
| 1.13E+01 | 2.40E+04 | 1.13E+01 | 5.72E−01 | 1.13E+01 | 1.09E+19 |
| 1.13E+01 | 2.42E+04 | 1.13E+01 | 9.54E+00 | 1.13E+01 | 1.37E+18 |
| 1.14E+01 | 2.38E+04 | 1.14E+01 | 1.91E+00 | 1.14E+01 | 2.74E+18 |
| 1.14E+01 | 2.39E+04 | 1.14E+01 | 3.81E+00 | 1.14E+01 | 1.37E+18 |
| 1.14E+01 | 2.43E+04 | 1.14E+01 | 3.81E+00 | 1.14E+01 | 9.57E+18 |
| 1.14E+01 | 2.41E+04 | 1.15E+01 | 5.72E−01 | 1.15E+01 | 1.37E+18 |
| 1.15E+01 | 2.41E+04 | 1.15E+01 | 5.72E+00 | 1.15E+01 | 4.10E+18 |
| 1.15E+01 | 2.43E+04 | 1.15E+01 | 5.72E+00 | 1.15E+01 | 4.10E+18 |
| 1.15E+01 | 2.40E+04 | 1.16E+01 | 5.72E+00 | 1.16E+01 | 6.84E+18 |
| 1.16E+01 | 2.36E+04 | 1.16E+01 | 5.72E+00 | 1.16E+01 | 2.74E+18 |
| 1.16E+01 | 2.41E+04 | 1.16E+01 | 5.72E−01 | 1.16E+01 | 1.37E+18 |
| 1.16E+01 | 2.38E+04 | 1.17E+01 | 5.72E−01 | 1.16E+01 | 6.84E+18 |
| 1.17E+01 | 2.38E+04 | 1.17E+01 | 3.81E+00 | 1.17E+01 | 4.10E+18 |
| 1.17E+01 | 2.39E+04 | 1.17E+01 | 5.72E−01 | 1.17E+01 | 2.74E+18 |
| 1.17E+01 | 2.43E+04 | 1.17E+01 | 1.91E+00 | 1.17E+01 | 4.10E+18 |
| 1.18E+01 | 2.40E+04 | 1.18E+01 | 1.91E+00 | 1.18E+01 | 4.10E+18 |
| 1.18E+01 | 2.41E+04 | 1.18E+01 | 5.72E+00 | 1.18E+01 | 4.10E+18 |
| 1.18E+01 | 2.39E+04 | 1.18E+01 | 3.81E+00 | 1.18E+01 | 5.47E+18 |
| 1.18E+01 | 2.41E+04 | 1.19E+01 | 1.91E+00 | 1.19E+01 | 2.74E+18 |
| 1.19E+01 | 2.41E+04 | 1.19E+01 | 1.91E+00 | 1.19E+01 | 4.10E+18 |
| 1.19E+01 | 2.40E+04 | 1.19E+01 | 3.81E+00 | 1.19E+01 | 2.74E+18 |
| 1.19E+01 | 2.43E+04 | 1.20E+01 | 5.72E+00 | 1.19E+01 | 4.10E+18 |
| 1.20E+01 | 2.40E+04 | 1.20E+01 | 5.72E−01 | 1.20E+01 | 2.74E+18 |
| 1.20E+01 | 2.42E+04 | 1.20E+01 | 3.81E+00 | 1.20E+01 | 1.37E+18 |
| 1.20E+01 | 2.41E+04 | 1.20E+01 | 5.72E−01 | 1.20E+01 | 4.10E+18 |
| 1.21E+01 | 2.40E+04 | 1.21E+01 | 5.72E−01 | 1.21E+01 | 4.10E+17 |
| 1.21E+01 | 2.41E+04 | 1.21E+01 | 3.81E+00 | 1.21E+01 | 4.10E+17 |
| 1.21E+01 | 2.44E+04 | 1.21E+01 | 5.72E−01 | 1.21E+01 | 1.23E+19 |
| 1.21E+01 | 2.39E+04 | 1.22E+01 | 5.72E−01 | 1.22E+01 | 1.37E+18 |
| 1.22E+01 | 2.41E+04 | 1.22E+01 | 1.91E+00 | 1.22E+01 | 1.37E+18 |
| 1.22E+01 | 2.40E+04 | 1.22E+01 | 1.91E+00 | 1.22E+01 | 6.84E+18 |
| 1.22E+01 | 2.40E+04 | 1.23E+01 | 5.72E−01 | 1.23E+01 | 2.74E+18 |
| 1.23E+01 | 2.42E+04 | 1.23E+01 | 1.91E+00 | 1.23E+01 | 5.47E+18 |
| 1.23E+01 | 2.39E+04 | 1.23E+01 | 5.72E+00 | 1.23E+01 | 4.10E+18 |
| 1.23E+01 | 2.42E+04 | 1.24E+01 | 3.81E+00 | 1.23E+01 | 4.10E+17 |
| 1.24E+01 | 2.44E+04 | 1.24E+01 | 3.81E+00 | 1.24E+01 | 5.47E+18 |
| 1.24E+01 | 2.43E+04 | 1.24E+01 | 3.81E+00 | 1.24E+01 | 4.10E+18 |
| 1.24E+01 | 2.48E+04 | 1.24E+01 | 5.72E−01 | 1.24E+01 | 4.10E+18 |
| 1.25E+01 | 2.41E+04 | 1.25E+01 | 5.72E−01 | 1.25E+01 | 2.74E+18 |
| 1.25E+01 | 2.42E+04 | 1.25E+01 | 5.72E−01 | 1.25E+01 | 1.37E+18 |
| 1.25E+01 | 2.41E+04 | 1.25E+01 | 5.72E−01 | 1.25E+01 | 9.57E+18 |
| 1.25E+01 | 2.43E+04 | 1.26E+01 | 1.91E+00 | 1.26E+01 | 5.47E+18 |
| 1.26E+01 | 2.43E+04 | 1.26E+01 | 5.72E−01 | 1.26E+01 | 4.10E+17 |
| 1.26E+01 | 2.43E+04 | 1.26E+01 | 5.72E+00 | 1.26E+01 | 4.10E+18 |
| 1.26E+01 | 2.43E+04 | 1.27E+01 | 3.81E+00 | 1.27E+01 | 5.47E+18 |
| 1.27E+01 | 2.41E+04 | 1.27E+01 | 3.81E+00 | 1.27E+01 | 2.74E+18 |
| 1.27E+01 | 2.46E+04 | 1.27E+01 | 3.81E+00 | 1.27E+01 | 1.37E+18 |
| 1.27E+01 | 2.43E+04 | 1.28E+01 | 5.72E+00 | 1.27E+01 | 4.10E+17 |
| 1.28E+01 | 2.42E+04 | 1.28E+01 | 3.81E+00 | 1.28E+01 | 4.10E+17 |
| 1.28E+01 | 2.46E+04 | 1.28E+01 | 1.91E+00 | 1.28E+01 | 4.10E+17 |
| 1.28E+01 | 2.43E+04 | 1.28E+01 | 1.91E+00 | 1.28E+01 | 4.10E+18 |
| 1.29E+01 | 2.45E+04 | 1.29E+01 | 5.72E−01 | 1.29E+01 | 5.47E+18 |
| 1.29E+01 | 2.42E+04 | 1.29E+01 | 3.81E+00 | 1.29E+01 | 2.74E+18 |
| 1.29E+01 | 2.39E+04 | 1.29E+01 | 5.72E−01 | 1.29E+01 | 4.10E+18 |
| 1.29E+01 | 2.41E+04 | 1.30E+01 | 5.72E−01 | 1.30E+01 | 1.09E+19 |
| 1.30E+01 | 2.41E+04 | 1.30E+01 | 3.81E+00 | 1.30E+01 | 6.84E+18 |
| 1.30E+01 | 2.45E+04 | 1.30E+01 | 5.72E−01 | 1.30E+01 | 2.74E+18 |
| 1.30E+01 | 2.44E+04 | 1.31E+01 | 1.91E+00 | 1.30E+01 | 4.10E+17 |
| 1.31E+01 | 2.38E+04 | 1.31E+01 | 3.81E+00 | 1.31E+01 | 2.74E+18 |
| 1.31E+01 | 2.44E+04 | 1.31E+01 | 5.72E−01 | 1.31E+01 | 1.37E+18 |
| 1.31E+01 | 2.41E+04 | 1.31E+01 | 1.91E+00 | 1.31E+01 | 1.37E+18 |
| 1.32E+01 | 2.41E+04 | 1.32E+01 | 1.91E+00 | 1.32E+01 | 2.74E+18 |
| 1.32E+01 | 2.41E+04 | 1.32E+01 | 1.91E+00 | 1.32E+01 | 4.10E+18 |
| 1.32E+01 | 2.43E+04 | 1.32E+01 | 3.81E+00 | 1.32E+01 | 2.74E+18 |
| 1.32E+01 | 2.45E+04 | 1.33E+01 | 5.72E+01 | 1.33E+01 | 1.37E+18 |
| 1.33E+01 | 2.44E+04 | 1.33E+01 | 3.81E+00 | 1.33E+01 | 4.10E+18 |
| 1.33E+01 | 2.42E+04 | 1.33E+01 | 1.91E+00 | 1.33E+01 | 2.74E+18 |
| 1.33E+01 | 2.43E+04 | 1.34E+01 | 1.91E+00 | 1.34E+01 | 1.37E+18 |
| 1.34E+01 | 2.41E+04 | 1.34E+01 | 1.91E+00 | 1.34E+01 | 4.10E+17 |
| 1.34E+01 | 2.45E+04 | 1.34E+01 | 5.72E+00 | 1.34E+01 | 2.74E+18 |
| 1.34E+01 | 2.44E+04 | 1.35E+01 | 1.91E+00 | 1.34E+01 | 1.37E+18 |
| 1.35E+01 | 2.46E+04 | 1.35E+01 | 1.91E+00 | 1.35E+01 | 1.37E+18 |
| 1.35E+01 | 2.44E+04 | 1.35E+01 | 5.72E−01 | 1.35E+01 | 4.10E+17 |
| 1.35E+01 | 2.39E+04 | 1.35E+01 | 5.72E+00 | 1.35E+01 | 1.37E+18 |
| 1.36E+01 | 2.39E+04 | 1.36E+01 | 1.91E+00 | 1.36E+01 | 4.10E+17 |
| 1.36E+01 | 2.40E+04 | 1.36E+01 | 1.91E+00 | 1.36E+01 | 4.10E+17 |
| 1.36E+01 | 2.40E+04 | 1.36E+01 | 1.91E+00 | 1.36E+01 | 1.37E+18 |
| 1.36E+01 | 2.44E+04 | 1.37E+01 | 1.91E+00 | 1.37E+01 | 2.74E+18 |
| 1.37E+01 | 2.46E+04 | 1.37E+01 | 5.72E−01 | 1.37E+01 | 4.10E+17 |
| 1.37E+01 | 2.44E+04 | 1.37E+01 | 1.91E+00 | 1.37E+01 | 2.74E+18 |
| 1.37E+01 | 2.41E+04 | 1.38E+01 | 1.91E+00 | 1.38E+01 | 2.74E+18 |
| 1.38E+01 | 2.42E+04 | 1.38E+01 | 1.91E+00 | 1.38E+01 | 5.47E+18 |
| 1.38E+01 | 2.40E+04 | 1.38E+01 | 5.72E−01 | 1.38E+01 | 4.10E+17 |
| 1.38E+01 | 2.46E+04 | 1.39E+01 | 5.72E−01 | 1.38E+01 | 1.37E+18 |
| 1.39E+01 | 2.47E+04 | 1.39E+01 | 1.91E+00 | 1.39E+01 | 2.74E+18 |
| 1.39E+01 | 2.41E+04 | 1.39E+01 | 1.91E+00 | 1.39E+01 | 4.10E+18 |
| 1.39E+01 | 2.40E+04 | 1.39E+01 | 5.72E−01 | 1.39E+01 | 2.74E+18 |
| 1.40E+01 | 2.44E+04 | 1.40E+01 | 1.91E+00 | 1.40E+01 | 5.47E+18 |
| 1.40E+01 | 2.42E+04 | 1.40E+01 | 5.72E+00 | 1.40E+01 | 1.37E+18 |
| 1.40E+01 | 2.44E+04 | 1.40E+01 | 1.91E+00 | 1.40E+01 | 1.37E+18 |
| 1.40E+01 | 2.41E+04 | 1.41E+01 | 1.91E+00 | 1.41E+01 | 4.10E+18 |
| 1.41E+01 | 2.44E+04 | 1.41E+01 | 1.91E+00 | 1.41E+01 | 5.47E+18 |
| 1.41E+01 | 2.41E+04 | 1.41E+01 | 1.91E+00 | 1.41E+01 | 1.37E+18 |
| 1.41E+01 | 2.36E+04 | 1.42E+01 | 3.81E+00 | 1.41E+01 | 1.37E+18 |
| 1.42E+01 | 2.43E+04 | 1.42E+01 | 3.81E+00 | 1.42E+01 | 2.74E+18 |
| 1.42E+01 | 2.42E+04 | 1.42E+01 | 5.72E−01 | 1.42E+01 | 4.10E+17 |
| 1.42E+01 | 2.45E+04 | 1.43E+01 | 5.72E−01 | 1.42E+01 | 4.10E+17 |
| 1.43E+01 | 2.44E+04 | 1.43E+01 | 3.81E+00 | 1.43E+01 | 2.74E+18 |
| 1.43E+01 | 2.51E+04 | 1.43E+01 | 1.91E+00 | 1.43E+01 | 2.74E+18 |
| 1.43E+01 | 2.43E+04 | 1.43E+01 | 1.91E+00 | 1.43E+01 | 2.74E+18 |
| 1.44E+01 | 2.44E+04 | 1.44E+01 | 5.72E−01 | 1.44E+01 | 2.74E+18 |
| 1.44E+01 | 2.45E+04 | 1.44E+01 | 3.81E+00 | 1.44E+01 | 2.74E+18 |
| 1.44E+01 | 2.41E+04 | 1.44E+01 | 1.91E+00 | 1.44E+01 | 4.10E+17 |
| 1.44E+01 | 2.44E+04 | 1.45E+01 | 3.81E+00 | 1.45E+01 | 2.74E+18 |
| 1.45E+01 | 2.45E+04 | 1.45E+01 | 3.81E+00 | 1.45E+01 | 4.10E+18 |
| 1.45E+01 | 2.46E+04 | 1.45E+01 | 5.72E−01 | 1.45E+01 | 6.84E+18 |
| 1.45E+01 | 2.45E+04 | 1.46E+01 | 1.91E+00 | 1.45E+01 | 1.37E+18 |

1. A method for fabricating an integrated circuit, the method comprising:
(a) providing a first region comprising silicon;
(b) forming a first nitrogen containing layer on the first region;
(c) removing a first portion of the first nitrogen containing layer but not a second portion of the first nitrogen containing layer, the second portion containing nitrogen;
(d) after the operation (c), heating the first region in an oxygen containing atmosphere to thermally oxidize at least some of the silicon under the second portion of the first nitrogen containing layer.

2. The method of claim 1 wherein the second portion of the first nitrogen containing layer comprises silicon oxide.

3. The method of claim 2 wherein the operation (d) provides a second nitrogen containing layer comprising the second portion of the first nitrogen containing layer and a silicon oxide formed by the operation (d);
wherein a peak nitrogen concentration in the second nitrogen containing layer is reached adjacent to a first surface of the second nitrogen containing layer, the first surface facing away from the first region.

4. The method of claim 2 wherein the operation (d) provides a second nitrogen containing layer comprising the second portion of the first nitrogen containing layer and a silicon oxide formed by the operation (d), the second nitrogen containing layer having a first surface facing away from the first region and a second surface adjacent to the silicon of the first region;
wherein the method further comprises:
(e) applying heat in a nitrogen containing atmosphere to increase the nitrogen concentration in the second nitrogen containing region adjacent to the second surface.

5. The method of claim 4 wherein a heating temperature in (e) is not higher than in (d).

6. The method of claim 4 wherein a heating temperature in (e) is below a heating temperature in (d).

7. The method of claim 6 wherein the heating temperature in (d) is at least 100° C.

8. The method of claim 4 wherein the second nitrogen containing layer comprises a first sub-region adjacent to the first surface of the second nitrogen containing layer and a second sub-region adjacent to the second surface of the second nitrogen containing layer;
wherein a maximum nitrogen concentration in the first sub-region and a maximum nitrogen concentration in the second sub-region are each higher than a maximum nitrogen concentration between the first and second sub-regions in the second nitrogen containing layer;
wherein a thickness of each of the first and second sub-regions is at most 33.3% of the thickness of the second nitrogen containing layer.

9. The method of claim 1 wherein the operation (d) provides a second nitrogen containing layer comprising the second portion of the first nitrogen containing layer and a silicon oxide formed by the operation (d); and
the method further comprises forming doped silicon on the second nitrogen containing layer.

10. A method for fabricating an integrated circuit, the method comprising:
forming a first nitrogen containing layer on a silicon region, the first nitrogen containing layer comprising a nitrided silicon oxide region adjacent to the silicon region;
removing a portion of the first nitrogen containing layer but not the nitrided silicon oxide region;
heating the silicon region in a nitrogen containing atmosphere to oxidize a portion of the silicon region and thus form a first silicon oxide layer on the silicon region, the first silicon oxide layer comprising the nitrided silicon oxide region.

11. The method of claim 10 further comprising forming a layer LI comprising doped silicon on the first silicon oxide layer, the first silicon oxide layer being located between the silicon region and the layer LI.

12. The method of claim 11 wherein either the silicon region or the doped silicon in the layer LI or both comprise boron.

13. An integrated circuit comprising:
a first region comprising a first surface comprising silicon; and
a dielectric region on the first surface, the dielectric region comprising a first surface adjacent to the first surface of the first region, the dielectric region comprising a second surface opposite to the first surface of the first region, the dielectric region comprising nitrogen atoms, wherein a peak nitrogen concentration in the dielectric region is reached less than 5 nm from the second surface.

14. The integrated circuit of claim 13 wherein the peak nitrogen concentration in the dielectric region is reached less than 3 nm from the second surface.

15. The integrated circuit of claim 13 wherein the peak nitrogen concentration in the dielectric region is reached less than 2 nm from the second surface.

16. The integrated circuit of claim 13 further comprising doped silicon on the second surface of the dielectric region, wherein the dielectric region is at least 1.5 nm thick.

17. An integrated circuit comprising:
a first region comprising a first surface comprising silicon; and
a dielectric region on the first surface, the dielectric region comprising a first surface adjacent to the first surface of the first region, the dielectric region comprising a second surface opposite to the first surface of the first region, the dielectric region comprising nitrogen atoms, wherein a nitrogen concentration in the dielectric region at 4 nm from the second surface is less than 10% of a peak nitrogen concentration in the dielectric region within 4 nm from the second surface.

18. The integrated circuit of claim 17 wherein the nitrogen concentration in the dielectric region at 4 nm from the second surface is less than 10% of a peak nitrogen concentration in the dielectric region within 3 nm from the second surface.

19. The integrated circuit of claim 17 further comprising doped silicon on the second surface of the dielectric region, wherein the dielectric region is at least 1.5 nm thick.
